(19) United States
(12) Patent Application Publication
(10) Pub. No.: US 2025/0159807 A1
(43) Pub. Date: May 15, 2025

(54) METALLIZED VIAS IN GLASS AND SILICON SUBSTRATES, INTERPOSERS, AND METHODS FOR PRODUCTION THEREOF

(71) Applicant: Kuprion Inc., Waterbury, CT (US)

(72) Inventors: Alfred A. Zinn, San Jose, CA (US); Randall M. Stoltenberg, Palo Alto, CA (US); Khanh Nguyen, San Jose, CA (US); Nhi Ngo, San Jose, CA (US); Alex Capanzana, San Jose, CA (US); Hannah Thanh Zinn, Palo Alto, CA (US)

(21) Appl. No.: 18/837,664

(22) PCT Filed: Feb. 15, 2023
(86) PCT No.: PCT/US2023/062676

§ 371 Date: Aug. 12, 2024

Related U.S. Application Data
(60) Provisional application No. 63/311,565, filed on Feb. 18, 2022.

(51) Int. Cl. H05K 1/11; H05K 3/40

(52) U.S. Cl. CPC H05K 1/115; H05K 3/4038; H05K 2201/0257; H05K 2201/026; H05K 2201/0323

(57) ABSTRACT

Substrates may be metallized by introducing a via fill material comprising one or more metals into one or more vias terminating in a base substrate and/or extending between a first face and a second face of the base substrate. More particularly, a glass or silicon base substrate may have one or more vias, in which a via fill material is present within the one or more vias. The via fill material comprises a porous matrix material having a void space of about 30% to about 60% and comprising a plurality of electrically conductive particles, which may be optionally bonded together with a cured silicate-reactive matrix material. A conductive network at least partially fills the void space within the porous matrix material, wherein the porous network comprises a plurality of metal nanoparticles that have been consolidated with one another.

### BACKGROUND

Modern electronic assemblies contain numerous interconnects between the various board components. The purpose of a given interconnect may be thermal, electrical, or structural in nature. Conventional interconnects are usually made from epoxies or tin- and/or lead-based solders due to their relatively low processing temperatures, and low material and processing costs. Unfortunately, these materials are not ideally suited for a number of applications, especially new high-performance electronics with large heat burdens, and current interconnects may exhibit several drawbacks and limitations as a result.

Most electronics made today are fabricated using printed circuit board (PCB) technology, which may include a number of interconnects therein, including many through-hole and blind vias to connect various conductive layers to each other. The term “printed circuit board” is somewhat of a misnomer, given that most boards are not truly printed and instead utilize photolithography to pattern a desired conductive circuit pattern (conductive traces) from a copper sheet bonded to a substrate. The copper sheet is first bonded to FR4 or a similar glass fiber epoxy laminate, and then much of the copper is etched away to leave behind one or more conductive traces upon the substrate in a desired pattern. Up to 90% of the copper sheet may be etched away in this process. Although the etched copper may be recovered, the etching process is time-consuming, labor-intensive, and may produce excessive quantities of hazardous waste. Most printed circuit boards are multi-layered, and this process needs to be repeated for each board layer, including drilling and filling vias for connecting board layers together, thus adding additional alignment and deformation concerns during hot-pressing board layers together. As a further complication, the poor thermal conductivity of glass fiber epoxy substrates may be problematic in various respects. While other types of substrates are of interest, processing issues regarding these alternative substrates have not yet been universally resolved. In a particular example, coefficient of thermal expansion (CTE) mismatch between the substrate and other components in an electrical interconnect, including heat dissipation systems, may be problematic, as discussed further below.

Ongoing demands for reduced chip sizes, increased functionality, and improved performance, all on a smaller footprint, are continuing to drive the need for heterogeneous integration in modern microelectronics components and systems. These developments are being facilitated by various packaging and electrical interconnect technologies such as wafer level fan out (WLFO), embedded multi-die interconnect bridge (EMIB), and interposer technologies. Interposers continue to be important for advanced electronic systems such as, for example, 2.5D and 3D integrated circuit and system-in-package (SIP) applications, given the proven benefits of interposers having through-surface vias (TSV).

Interposers are becoming increasingly prevalent as components (e.g., incorporated within system-in-package (SIP) and system on chip (SOC) configurations) within printed circuit boards to establish electrical and/or thermal communication between the various electronic components therein. Interposers commonly used for packaging applications fall into three main categories: silicon, organics (polymers), and glass. Each of these interposer material classes faces its own challenges with respect to electrical, mechanical, and thermal properties for producing high-performance electronic devices. Namely, like other types of interconnects presently used in printed circuit boards, there are issues associated with current classes of interposers, such as limited thermal conductivity and/or poor bonding to metallic components. CTE (coefficient of thermal expansion) mismatch at one or more interconnects may lead to thermomechanical stress during repeated heating and cooling cycles as well. For interposers having a large surface area, the effects of CTE mismatch may be especially problematic.

Silicon interposers have long played a key role in 2.5D and 3D IC chip integration due to their high fine pitch density and TSV formation capabilities. Silicon is a proven technology, has been commercially used in a number of high-performance computing systems, and is currently favored in platforms using heterogeneous integration. However, silicon technology faces performance limitations caused by the TSV profile and microfluidic thermal design changes resulting from the need to mitigate thermal issues. High cost is another key challenge to overcome for continued adoption in the marketplace. For example, when used in a device, silicon interposers can add as much as $30 for a medium-sized chip or even over $100 for a larger-sized chip. Cost considerations have limited silicon interposers to high-speed networking and server chip applications where cost is less of a driver.

Organic interposers are one alternative being explored to reduce cost, as well as provide a favorably low dielectric constant. Organic interposers offer lower material costs and feature a well-established supply chain, as well as the ability to be manufactured using traditional processes such as wet etching. The main challenge of organic interposers lies in their limited stiffness, especially for very thin substrates. Organic interposers also lack the ability to achieve the fine pitch density possible with silicon and glass interposers. Organic interposers are currently well suited for applications such as, for example, logic-memory integration, large central processing units (CPUs)/graphics processing units (GPUs), high-performance RF applications, and certain types of application-specific integrated chips (ASICs), although they are also usable in other applications in some instances.

Glass interposers are a logical low-cost, high-performance alternative interposer technology promising higher interconnect density than organic interposers and a significantly lower cost compared to silicon interposers with similar interconnect density. Therefore, glass interposers are seeing an increased adoption rate in ultra-high pitch density applications, such as, for example, in communications, network and signal processing and testing, high-bandwidth memory (HBM), high-performance computing, and radiofrequency (RF) technology. In addition, glass interposers are being increasingly adopted in low-cost packaging such as, for example, micro-electromechanical systems (MEMS), sensors, power, and analog devices. In addition to their lower costs, glass interposers are also available in large panel forms. The key challenges associated with glass interposers include surface defects during manufacturing that can lead to cracking and low thermal conductivity. In addition, there are limitations in effective diameter achievable for through glass vias (TGV) due to large CTE mismatches of glass with conductive materials like copper, thereby effectively precluding the use of larger vias. Still, glass interposers promise to be a readily available solution for addressing current and future needs in the electronics industry.

With the proliferation of developments such as the Internet of Things (IoT), connected and self-driving cars, and similar devices, the push for high-bandwidth data processing and communications in combination with high-performance electronic systems has become increasingly important. Although interposers may find use in a number of different types of electronic systems, the foregoing is a leading driver of the interposer market, since chip scaling has reached economical limits, and packaging has become a key focus for advancing electronics on a chip-scale. Continued growth of interposer technology is dependent on addressing challenges, performance, and cost barriers induced by the interposer materials themselves in these applications as well as others.

### BRIEF DESCRIPTION OF THE DRAWINGS

The following figures are included to illustrate certain aspects of the present disclosure, and should not be viewed as exclusive embodiments. The subject matter disclosed is capable of considerable modifications, alterations, combinations, and equivalents in form and function, as will occur to one having ordinary skill in the art and having the benefit of this disclosure.

FIGS. 1 and 2 are diagrams of presumed structures of metal nanoparticles having a surfactant coating thereon.

FIG. 3 is a diagram of a metallized substrate of the present disclosure containing filled vias.

FIGS. 4A and 4B are images of a glass substrate coated with a seed layer containing copper particles before and after polishing, respectively.

FIG. 5 is an image of a metallized glass substrate.

FIG. 6A is a diagram of a metallized substrate of the present disclosure further having a seed layer and a continuous metallization layer disposed thereon. FIG. 6B is a diagram of a metallized substrate of the present disclosure after etching of the continuous metallization layer to introduce conductive traces upon the metallized substrate.

### DETAILED DESCRIPTION

The present disclosure is generally directed to electronic assemblies and, more specifically, metallized substrates that are suitable for use in electronic assemblies.

There are multiple types of interconnects that may be present in a printed circuit board or similar type of electronic assembly, including within an interposer. Conventionally, interconnects are formed with epoxy or solder, or using vias filled with an electroplated metal such as copper. Despite their common use, epoxies and solders have limitations that are oftentimes not readily overcome with conventional materials. Limited thermal conductivity, poor thermal stability, and CTE (coefficient of thermal expansion) mismatch may be problematic in many instances, for example, especially in high-performance electronic devices with significant heat burdens. Electroplated copper is additionally problematic to deposit on glass and silicon substrates commonly utilized for interposers.

Conventional filling techniques for vias include electroplating processes, which may be slow, expensive, and prone toward incomplete via filling, sometimes due to closing off the end of the via before filling is otherwise complete. There are also limits to the sizes and aspect ratios of vias that can be filled effectively. Narrow vias with a high aspect ratio and/or blind vias are often difficult to fill reliably. Vias having a large diameter can similarly be problematic to fill through electroplating, since deposition rates are slow. Both through-plane vias and vias that terminate in a base substrate (blind vias) may be problematic in regard to the foregoing.

Glass substrates and silicon substrates may be desirable to incorporate in electronic assemblies, including as interposer substrates, due to their low electrical conductivity and favorable RF performance, but the CTE mismatch and poor through-plane thermal conductivity of these types of substrates may be problematic. In addition, robust bonding of metal upon glass and silicon substrates may be difficult to achieve.

The present disclosure describes metallized glass or silicon substrates having one or more vias extending therethrough, in which the vias are first loaded with a via fill material comprising a porous matrix having significant void space therein (e.g., 30-50% void volume in the form of interconnected pores) that is subsequently at least partially filled with a conductive network formed from consolidated metal nanoparticles. Blind vias terminating in the base substrate without extending all the way through may be loaded with a via fill material in a similar manner. The porous matrix comprises a plurality of electrically conductive particles, which may be optionally bonded together with a cured silicate-reactive matrix material. When used, curing of the silicate-reactive matrix material may occur at low temperatures around room temperature up to about 100° C. (˜8-12 minute curing time), with a significant degree of porosity resulting from packing limitations of the electrically conductive particles. In addition to binding the electrically conductive particles together, the silicate-reactive matrix material may also undergo a reaction with the glass or silica upon curing to adhere the via fill material to the walls of the one or more vias by way of a chemical reaction. The chemical bonding helps promote retention of the via fill material within the one or more vias, and may decrease propensity toward cracking and shrinkage during metal nanoparticle consolidation. Other advantages, such as hermetic sealing, discussed further below, may be realized as well. Other than affording vias that are not fully hermetically sealed, via fill materials lacking the cured silicate-reactive matrix material may similarly afford a porous structure within vias that may be at least partially filled with a conductive network formed from consolidated metal nanoparticles and retained within the via. Regardless of whether a cured silicate-reactive matrix material is present, the metal nanoparticles may be formulated to afford CTE matching with the glass or silicon substrate as well, thereby affording even more robust thermal performance and electrical conductivity performance, as well as facilitating use of larger thermal vias with high reliability.

Loading of metal nanoparticles within the void space of the via fill material may be accomplished by infiltrating the void space with a metal nanoparticle composition (e.g., by vacuum or pressure infiltration) that is sufficient fluid to enter the void volume under sufficient infiltration conditions. Metal nanoparticles and metal nanoparticle compositions provide a number of advantages for infiltrating the void space and forming a conductive network therein, as discussed hereinbelow. In establishing the conductive network, bonding to the larger electrically conductive particles introduced in forming the porous matrix may also take place. Although vias may be filled with the via fill material and the metal nanoparticle composition sequentially, in some instances, it may be possible to fill vias with the via fill material and the metal nanoparticle composition already combined together prior to introduction to the vias.

By loading the one or more vias with the via fill material and establishing a conductive network therein, a number of benefits may be realized. At the least, a highly conductive electrical and thermal pathway may be established through-plane between the first and second faces of the glass or silicon substrate, regardless of whether a cured silicate-reactive matrix material is present or not. When a silicate-reactive matrix material is present and subsequently cured, chemical bonding of the cured silicate-reactive matrix material to the via walls may be realized, which may afford hermetic sealing of the via walls. Such hermetic sealing may lead to fewer impacts due to shrinkage as metal nanoparticles undergo consolidation with one another. The resulting improvement in structural integrity may further decrease the likelihood of the via fill material becoming dislodged during heating and cooling cycles due to repeated thermal expansion and contraction. Additional protection against thermal expansion and contraction issues may be realized by using a metal nanoparticle composition tailored to provide CTE matching with the substrate and the via fill material.

Further advantageously, a related approach using a silicate-reactive matrix material may be utilized to form a metallization layer upon the surface of the glass or silicon base substrates. In particular, a seed layer formed from the silicate-reactive matrix material and a plurality of electrically conductive particles may be utilized to deposit one or more conductive traces or a metallization layer on at least one of the first or second faces of the base substrate. The one or more conductive traces may be obtained by direct printing of a metal nanoparticle composition or through selective etching of a continuous metallization layer obtained through printing of a metal nanoparticle composition. The conductive traces may be in electrical communication with at least a portion of the one or more vias, either through a direct connection or indirectly through a bonding pad located at the via opening. Thus, in some instances, similar types of formulations may be used for via filling and for forming a seed layer upon a surface of a glass or silicon substrate. It is to be recognized, however, that the specific formulations used in each location may differ in the concentration of one or more components therein. Likewise, a metal nanoparticle composition deposited upon the seed layer and subsequently converted to conductive traces or a metallization layer through metal nanoparticle consolidation may similarly be CTE-matched to the substrate to afford more robust thermal performance as well. The seed layer may afford robust adherence of the conductive traces or the metallization layer to the glass or silicon substrate, which is otherwise not possible through direct metal printing upon these types of materials. The electrically conductive particles in the seed layer may comprise micron-size metal particles, metal nanoparticles, conductive nanomaterials, or any combination thereof.

The seed layer may be deposited upon the glass or silicon substrate in an initially non-conductive or low-conductivity state. After mechanical polishing of the seed layer, the electrical conductivity may surprisingly improve. Establishing electrical conductivity within the seed layer by mechanical polishing may provide dual benefits. First, enhanced adherence of a metallization layer or conductive trace to the seed layer may be realized. Second, electrical conductivity of a conductive trace includes the combined conductivity of the seed layer and a metallization layer formed thereon. Thus, increasing the electrical conductivity of the seed layer may also increase the electrical conductivity of the resulting conductive trace. Finally, by rendering the seed layer electrically conductive, metallization strategies such as electroplating may be conducted, which may be satisfactory for forming a metallization layer in some instances (e.g., instead of forming a metal trace by consolidating metal nanoparticles). Electroless plating or consolidating metal nanoparticles to form a metallization layer, in contrast, may be conducted with the seed layer in either a conductive state or a non-conductive state.

Once the seed layer has been deposited and optionally rendered electrically conductive, the seed layer may be at least partially metallized to form a metal layer upon the seed layer. Metallization may take place by electroplating or electroless plating techniques, or more desirably using metal nanoparticle compositions. In contrast to plating techniques, metal nanoparticle compositions may be deposited and consolidated upon the seed layer to form either a thick metallization layer over substantially the entire surface of the seed layer or only in specified locations using direct printing techniques. Metallization layer thicknesses attainable by metal nanoparticle consolidation may range from as small as about 10 microns up to about 5000 microns (5 mm), or about 10 microns to about 500 microns, or about 500 microns to about 1000 microns, or about 1000 microns to about 3000 microns. Plating techniques may afford very thin metallization layer thicknesses, in contrast, such as layer thicknesses of about 50 microns or less, or about 10 microns or less. Direct printing techniques using metal nanoparticle compositions may afford conductive traces upon the surface of the substrate in specified locations, whereas etching techniques are limited to forming conductive traces by etching of the entirety of the metallization layer in specified locations. Electrical isolation between conductive traces may be realized by depositing the seed layer only in locations where conductive traces are to be formed and/or by etching the seed layer after forming conductive traces in desired locations to limit conductivity therebetween.

As described in further detail below, metal nanoparticle compositions may be processed at relatively low temperatures (˜200° C.-250° C.) to form bulk metal in accomplishing the foregoing. As a further advantage, metal nanoparticle compositions may be formulated to afford CTE matching with the substrate, both within the vias and upon the substrate surface, thereby promoting more robust performance than is possible with conventional materials. As a metal within the via fill material and the conductive traces, copper is desirable due to its low cost and high electrical conductivity, although other metals may be used as well. In addition, the high thermal conductivity of copper may be advantageous when incorporated within the via fill material in order to promote heat transfer from one face of the substrate to the other. Copper and other highly conductive metals, including mixtures or alloys thereof, may be present as the metal particles in the seed layer as well. Mixtures or alloys containing copper may be advantageous for affording improved oxidation resistance, for example.

As described herein, low-temperature processing of metal nanoparticles, including copper nanoparticles, is made possible by the heightened activity of the metal nanoparticles compared to the corresponding bulk metal. As a result, metal nanoparticles may fuse (consolidate) together at a temperature much lower than the metal melting point to afford bulk metal within the via fill and upon the seed layer. Formation of the bulk metal may be accomplished at processing temperatures that would be incompatible with various electronic components if working with bulk metal directly in molten form. Once the metal nanoparticles have been fused together, properties similar to those of the corresponding bulk metal may be realized, but with the ability to tailor the CTE or other properties through formulation of the metal nanoparticle composition.

Before further discussing the embodiments of the present disclosure in further detail, a brief description of metal nanoparticles and metal nanoparticle compositions suitable for use in the present disclosure will first be provided, with copper nanoparticles being a representative example of metal nanoparticles that may be present as a majority metal nanoparticle in the metal nanoparticle compositions. Metal nanoparticles exhibit a number of properties that can differ significantly from those of the corresponding bulk metal. One property of metal nanoparticles that can be of particular importance is nanoparticle fusion or consolidation that occurs at the metal nanoparticles' fusion temperature. As used herein, the term “fusion temperature” refers to the temperature at which a metal nanoparticle liquefies, thereby giving the appearance of melting. As used herein, the terms “fusion,” “sintering” and “consolidation” synonymously refer to the coalescence or partial coalescence of metal nanoparticles with one another to form a larger mass (sintered mass) of bulk metal, thereby defining a bulk metal matrix, such as bulk copper matrix. During nanoparticle fusion, the metal nanoparticles undergo consolidation to form the bulk metal matrix without proceeding through a liquid state.

Upon decreasing in size, particularly below about 200 nm in equivalent spherical diameter, the temperature at which metal nanoparticles coalesce drops dramatically from that of the corresponding bulk metal. For example, copper nanoparticles having a size of about 150 nm or less can have fusion temperatures of about 240° C. or below, or about 220° C. or below, or about 200° C. or below, in comparison to bulk copper's melting point of 1084° C. Some of the metal nanoparticles may be about 20 nm or less in size, which may have especially low fusion temperatures and promote consolidation of larger metal nanoparticles. Thus, the consolidation of metal nanoparticles taking place at the fusion temperature can allow objects containing a bulk metal matrix, such as one or more interconnects in an electronic assembly, a metallization layer, and/or one or more conductive traces, to be fabricated at significantly lower processing temperatures than when working directly with the bulk metal itself as a starting material. Once the bulk metal matrix has been formed, the melting point of the bulk metal matrix resembles that of the bulk metal itself and contains a plurality of grain boundaries. In addition, the bulk metal matrix may have a defined nanoporosity that is not present within the corresponding bulk metal.

As used herein, the term “metal nanoparticle” refers to metal particles that are about 200 nm or less in size, without particular reference to the shape of the metal particles. As used herein, the term “copper nanoparticle” refers to a metal nanoparticle made from copper or predominantly copper.

As used herein, the term “micron-size metal particles” refers to metal particles that are about 250 nm or greater in size in at least one dimension, without particular reference to the shape of the metal particles.

The terms “consolidate,” “consolidation” and other variants thereof are used interchangeably herein with the terms “fuse,” “fusion” and other variants thereof.

As used herein, the terms “partially fused,” “partial fusion,” and other derivatives and grammatical equivalents thereof refer to the partial coalescence of metal nanoparticles with one another. Whereas totally fused metal nanoparticles retain essentially none of the structural morphology of the original unfused metal nanoparticles (i.e., they resemble bulk metal with minimal grain boundaries), partially fused metal nanoparticles retain at least some of the structural morphology of the original unfused metal nanoparticles. The properties of partially fused metal nanoparticles can be intermediate between those of the corresponding bulk metal and the original unfused metal nanoparticles.

A number of scalable processes for producing bulk quantities of metal nanoparticles in a targeted size range have been developed. Most typically, such processes for producing metal nanoparticles take place by reducing a metal precursor in the presence of one or more surfactants. The metal nanoparticles can then be isolated and purified from the reaction mixture by common isolation techniques and processed into a paste composition, if desired.

Any suitable technique can be employed for forming the metal nanoparticles used in the metal nanoparticle compositions and processes described herein. Particularly facile metal nanoparticle fabrication techniques are described in U.S. Pat. Nos. 7,736,414, 8,105,414, 8,192,866, 8,486,305, 8,834,747, 9,005,483, 9,095,898, and 9,700,940, each of which is incorporated herein by reference in its entirety. As described therein, metal nanoparticles can be fabricated in a narrow size range by reduction of a metal salt in a solvent in the presence of a suitable surfactant system, which can include one or more different surfactants. Further description of suitable surfactant systems follows below. Without being bound by any theory or mechanism, it is believed that the surfactant system can mediate the nucleation and growth of the metal nanoparticles, limit surface oxidation of the metal nanoparticles, and/or inhibit metal nanoparticles from extensively aggregating with one another prior to being at least partially fused together. Suitable organic solvents for solubilizing metal salts and forming metal nanoparticles can include, for example, formamide, N,N-dimethylformamide, dimethyl sulfoxide, dimethylpropylene urea, hexamethylphosphoramide, tetrahydrofuran, and glyme, diglyme, triglyme, and tetraglyme. Reducing agents suitable for reducing metal salts and promoting the formation of metal nanoparticles can include, for example, an alkali metal in the presence of a suitable catalyst (e.g., lithium naphthalide, sodium naphthalide, or potassium naphthalide) or borohydride reducing agents (e.g., sodium borohydride, lithium borohydride, potassium borohydride, or tetraalkylammonium borohydrides).

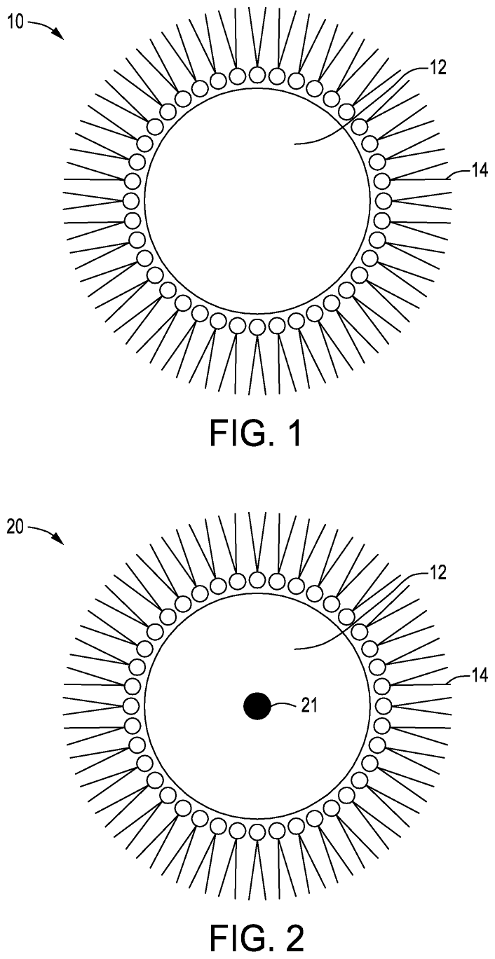

FIGS. 1 and 2 are diagrams of presumed structures of metal nanoparticles having a surfactant coating thereon. As shown in FIG. 1, metal nanoparticle 10 includes metallic core 12 and surfactant layer 14 overcoating metallic core 12. Surfactant layer 14 can contain any combination of surfactants, as described in more detail below. Metal nanoparticle 20, shown in FIG. 2, is similar to that depicted in FIG. 1, except metallic core 12 is grown about nucleus 21, which can be a metal that is the same as or different than that of metallic core 12. Because nucleus 21 is buried deep within metallic core 12 in metal nanoparticle 20, it is not believed to significantly affect the overall nanoparticle properties. In some embodiments, nucleus 21 may comprise a substance that is a grain growth inhibitor, which may be released as the metal nanoparticles undergo consolidation with one another. In some embodiments, the nanoparticles can have an amorphous morphology.

As discussed above, the metal nanoparticles have a surfactant coating containing one or more surfactants upon their surface. The surfactant coating can be formed on the metal nanoparticles during their synthesis. The surfactant coating is generally lost during consolidation of the metal nanoparticles upon heating above the fusion temperature. Formation of a surfactant coating upon metal nanoparticles during their syntheses can desirably limit the ability of the metal nanoparticles to fuse to one another before heating above the fusion temperature, limit agglomeration of the metal nanoparticles, and promote the formation of a population of metal nanoparticles having a narrow size distribution.

Copper can be a particularly desirable metal in the embodiments of the present disclosure due to its low cost, strength, and excellent electrical and thermal conductivity values, as well as additional advantages addressed further herein. Although copper nanoparticles may be advantageous for use in the embodiments herein, it is to be appreciated that other types of metal nanoparticles may be used in alternative embodiments. Other metal nanoparticles that may be useful in electronic applications for forming a bulk metal matrix include, for example, aluminum nanoparticles, palladium nanoparticles, silver nanoparticles, gold nanoparticles, iron nanoparticles, cobalt nanoparticles, nickel nanoparticles, titanium nanoparticles, zirconium nanoparticles, hafnium nanoparticles, tantalum nanoparticles, and the like. Micron-sized particles of these metals may be present in metal nanoparticle compositions containing the metal nanoparticles as well, which may provide processing advantages in some cases.

In various embodiments, the surfactant system present within the metal nanoparticles can include one or more surfactants. The differing properties of various surfactants can be used to tailor the properties of the metal nanoparticles. Factors that can be taken into account when selecting a surfactant or combination of surfactants for inclusion upon the metal nanoparticles can include, for example, ease of surfactant dissipation from the metal nanoparticles during nanoparticle fusion, nucleation and growth rates of the metal nanoparticles, the metal component of the metal nanoparticles, and the like.

In some embodiments, an amine surfactant or combination of amine surfactants, particularly aliphatic amines, can be present upon the metal nanoparticles. Amine surfactants can be particularly desirable for use in conjunction with copper nanoparticles. In some embodiments, two amine surfactants can be used in combination with one another. In other embodiments, three amine surfactants can be used in combination with one another. In more specific embodiments, a primary amine, a secondary amine, and a diamine chelating agent can be used in combination with one another. In still more specific embodiments, the three amine surfactants can include a long chain primary amine, a secondary amine, and a diamine having at least one tertiary alkyl group nitrogen substituent. Further disclosure regarding suitable amine surfactants follows hereinafter.

In some embodiments, the surfactant system can include a primary alkylamine. In some embodiments, the primary alkylamine can be a C₂-C₁₈ alkylamine. In some embodiments, the primary alkylamine can be a C₇-C₁₀ alkylamine. In other embodiments, a C₅-C₆ primary alkylamine can also be used. Without being bound by any theory or mechanism, the exact size of the primary alkylamine can be balanced between being long enough to provide an effective inverse micelle structure during synthesis versus having ready volatility and/or ease of handling during nanoparticle consolidation. For example, primary alkylamines with more than 18 carbons can also be suitable for use in the present embodiments, but they can be more difficult to handle because of their waxy character. C₇-C₁₀ primary alkylamines, in particular, can represent a good balance of desired properties for ease of use.

In some embodiments, the C₂-C₁₈ primary alkylamine can be n-hexylamine, n-heptylamine, n-octylamine, n-nonylamine, or n-decylamine, for example. While these are all straight chain primary alkylamines, branched chain primary alkylamines can also be used in other embodiments. For example, branched chain primary alkylamines such as, for example, 7-methyloctylamine, 2-methyloctylamine, or 7-methylnonylamine can be used. In some embodiments, such branched chain primary alkylamines can be sterically hindered where they are attached to the amine nitrogen atom. Non-limiting examples of such sterically hindered primary alkylamines can include, for example, t-octylamine, 2-methylpentan-2-amine, 2-methylhexan-2-amine, 2-methylheptan-2-amine, 3-ethyloctan-3-amine, 3-ethylheptan-3-amine, 3-ethylhexan-3-amine, and the like. Additional branching can also be present. Without being bound by any theory or mechanism, it is believed that primary alkylamines can serve as ligands in the metal coordination sphere but be readily dissociable therefrom during metal nanoparticle consolidation.

In some embodiments, the surfactant system can include a secondary amine. Secondary amines suitable for forming metal nanoparticles can include normal, branched, or cyclic C₄-C₁₂ alkyl groups bound to the amine nitrogen atom. In some embodiments, the branching can occur on a carbon atom bound to the amine nitrogen atom, thereby producing significant steric encumbrance at the nitrogen atom. Suitable secondary amines can include, without limitation, dihexylamine, diisobutylamine, di-t-butylamine, dineopentylamine, di-t-pentylamine, dicyclopentylamine, dicyclohexylamine, and the like. Secondary amines outside the C₄-C₁₂ range can also be used, but such secondary amines can have undesirable physical properties such as low boiling points or waxy consistencies that can complicate their handling.

In some embodiments, the surfactant system can include a chelating agent, particularly a diamine chelating agent. In some embodiments, one or both of the nitrogen atoms of the diamine chelating agent can be substituted with one or two alkyl groups. When two alkyl groups are present on the same nitrogen atom, they can be the same or different. Further, when both nitrogen atoms are substituted, the same or different alkyl groups can be present. In some embodiments, the alkyl groups can be C₁-C₆ alkyl groups. In other embodiments, the alkyl groups can be C₁-C₄ alkyl groups or C₃-C₆ alkyl groups. In some embodiments, C₃ or higher alkyl groups can be straight or have branched chains. In some embodiments, C₃ or higher alkyl groups can be cyclic. Without being bound by any theory or mechanism, it is believed that diamine chelating agents can facilitate metal nanoparticle formation by promoting nanoparticle nucleation.

In some embodiments, suitable diamine chelating agents can include N,N′-dialkylethylenediamines, particularly C₁-C₄ N,N′-dialkylethylenediamines. The corresponding methylenediamine, propylenediamine, butylenediamine, pentylenediamine or hexylenediamine derivatives can also be used. The alkyl groups can be the same or different. C₁-C₄ alkyl groups that can be present include, for example, methyl, ethyl, propyl, and butyl groups, or branched alkyl groups such as isopropyl, isobutyl, s-butyl, and t-butyl groups. Illustrative N,N′-dialkylethylenediamines that can be suitable for inclusion upon metal nanoparticles include, for example, N,N′-di-t-butylethylenediamine, N,N′-diisopropylethylenediamine, and the like.

In some embodiments, suitable diamine chelating agents can include N,N,N′,N′-tetraalkylethylenediamines, particularly C₁-C₄ N,N,N′,N′-tetraalkylethylenediamines. The corresponding methylenediamine, propylenediamine, butylenediamine, pentylenediamine or hexylenediamine derivatives can also be used. The alkyl groups can again be the same or different and include those mentioned above. Illustrative N,N,N′,N′-tetraalkylethylenediamines that can be suitable for use in forming metal nanoparticles include, for example, N,N,N′,N′-tetramethylethylenediamine, N,N,N′,N′-tetraethylethylenediamine, and the like.

Surfactants other than aliphatic amines can also be present in the surfactant system. In this regard, suitable surfactants can include, for example, pyridines, aromatic amines, phosphines, thiols, or any combination thereof. These surfactants can be used in combination with an aliphatic amine, including those described above, or they can be used in a surfactant system in which an aliphatic amine is not present. Further disclosure regarding suitable pyridines, aromatic amines, phosphines, and thiols follows below.

Suitable aromatic amines can have a formula of ArNR¹R², where Ar is a substituted or unsubstituted aryl group and R¹ and R² are the same or different. R¹ and R² can be independently selected from H or an alkyl or aryl group containing from 1 to about 16 carbon atoms. Illustrative aromatic amines that can be suitable for use in forming metal nanoparticles include, for example, aniline, toluidine, anisidine, N,N-dimethylaniline, N,N-diethylaniline, and the like. Other aromatic amines that can be used in conjunction with metal nanoparticles can be envisioned by one having ordinary skill in the art.

Suitable pyridines can include both pyridine and its derivatives. Illustrative pyridines that can be suitable for use inclusion upon metal nanoparticles include, for example, pyridine, 2-methylpyridine, 2,6-dimethylpyridine, collidine, pyridazine, and the like. Chelating pyridines such as bipyridyl chelating agents may also be used. Other pyridines that can be used in conjunction with metal nanoparticles can be envisioned by one having ordinary skill in the art.

Suitable phosphines can have a formula of PR₃, where R is an alkyl or aryl group containing from 1 to about 16 carbon atoms. The alkyl or aryl groups attached to the phosphorus center can be the same or different. Illustrative phosphines that can be present upon metal nanoparticles include, for example, trimethylphosphine, triethylphosphine, tributylphophine, tri-t-butylphosphine, trioctylphosphine, triphenylphosphine, and the like. Phosphine oxides can also be used in a like manner. In some embodiments, surfactants that contain two or more phosphine groups configured for forming a chelate ring can also be used. Illustrative chelating phosphines can include 1,2-bisphosphines, 1,3-bisphosphines, and bisphosphines such as BINAP, for example. Other phosphines that can be used in conjunction with metal nanoparticles can be envisioned by one having ordinary skill in the art.

Suitable thiols can have a formula of RSH, where R is an alkyl or aryl group having from about 4 to about 16 carbon atoms. Illustrative thiols that can present upon metal nanoparticles include, for example, butanethiol, 2-methyl-2-propanethiol, hexanethiol, octanethiol, benzenethiol, and the like. In some embodiments, surfactants that contain two or more thiol groups configured for forming a chelate ring can also be used. Illustrative chelating thiols can include, for example, 1,2-dithiols (e.g., 1,2-ethanethiol) and 1,3-dithiols (e.g., 1,3-propanethiol). Other thiols that can be used in conjunction with metal nanoparticles can be envisioned by one having ordinary skill in the art.

The metal nanoparticles described hereinabove can be incorporated within various metal nanoparticle compositions, which may facilitate dispensation thereof for forming a connection, filling vias, or forming a metallization layer of the present disclosure. Illustrative disclosure directed to such metal nanoparticle compositions follows hereinafter. Copper nanoparticle compositions may be particularly useful for forming a metallization layer or infiltrating a via fill material in the disclosure herein, especially in the presence of a grain growth inhibitor or CTE modifier for metallization layers, conductive traces, or components that may be exposed to high operating temperatures, particularly with repeated thermal cycling. The metal nanoparticle compositions may further be formulated to confer oxidation resistance within a via fill material, a metallization layer or conductive traces formed therefrom.

Metal nanoparticle compositions can be prepared by dispersing as-produced or as-isolated metal nanoparticles in an organic matrix containing one or more organic solvents and various other optional components. As used herein, the terms “nanoparticle paste formulation” and “nanoparticle paste composition” may be used interchangeably and refer synonymously to a fluid composition containing dispersed metal nanoparticles that is suitable for dispensation using a desired technique. The viscosity may vary over a wide range depending on the chosen dispensation technique. Use of the term “paste” does not necessarily imply an adhesive function of the paste alone. Through judicious choice of the organic solvent(s) and other additives, the loading of metal nanoparticles and the like, dispensation of the metal nanoparticles in a desired location may be promoted and the properties of a metal matrix (layer) resulting therefrom may be tailored.

Cracking and shrinkage can sometimes occur during consolidation of the metal nanoparticles within the metal nanoparticle compositions. One way in which the metal nanoparticle compositions can promote a decreased degree of cracking, shrinkage and void formation following metal nanoparticle consolidation is by maintaining a high solids content. More particularly, in some embodiments, the metal nanoparticle compositions can contain at least about 30% metal nanoparticles by weight, particularly about 30% to about 97% metal nanoparticles by weight of the composition, or about 50% to about 97% metal nanoparticles by weight of the composition, or about 70% to about 97% metal nanoparticles by weight of the composition. Moreover, in some embodiments, small amounts (e.g., about 0.01% to about 15% or about 35% or about 60% by weight of the composition) of micron-size metal particles can be present in addition to the metal nanoparticles. Such micron-size metal particles can desirably promote the fusion of metal nanoparticles into a contiguous mass and further reduce the incidence of cracking and shrinkage. Instead of being liquefied and undergoing direct consolidation, the micron-size metal particles can simply become joined together upon being contacted with metal nanoparticles that have been raised above their fusion temperature. Essentially, the metal nanoparticles may function like “glue” that joins the micron-size metal particles together. These factors can reduce the porosity after fusing the metal nanoparticles together, as well as provide tailoring of the CTE. The micron-size metal particles can include the same or different metals than the metal nanoparticles, and suitable metals for the micron-size particles can include, for example, copper, silver, gold, aluminum, tin, and the like. Micron-size graphite particles may also be included, in some embodiments. Carbon nanotubes and/or graphene may be included, in some embodiments. Still other additives in the micron-size range, such as diamond particles or cubic BN (boron nitride) may be included as well.

During consolidation, the copper matrix defined by fused copper nanoparticles is characterized by a very fine, uniformly distributed nanoporosity (typically 4-15% with a pore size in the range of about 100 nm to about 300 nm, and mostly closed pores) that limits hot spots by ensuring uniform heat distribution across an interface. However, the nanoporosity may range from about 2% to about 15% (i.e., 85%-98% dense fused copper nanoparticles or other types of fused nanoparticles with closed pore nanoporosity and a pore size ranging from about 50 nm to about 500 nm, or about 100 nm to about 300 nm, or about 150 nm to about 250 nm). Several copper bulk matrices described further below specify a bulk copper matrix having a density of at least 90%. However, it is to be appreciated that this value is representative of the density values that may be attained for the bulk copper matrices resulting from consolidation of copper nanoparticles and other types of metal nanoparticles, particularly a density ranging from about 85% to about 98%. Thus, the bulk copper matrices formed through consolidation of copper nanoparticles according to the disclosure herein may have a density ranging from about 85% to about 98% relative to bulk copper. The nanoporosity may reside within a similar range.

Micron-size metal particles may be differentiated from grain growth inhibitors in the disclosure herein, since micron-size metal particles are less readily incorporated within grain boundaries between consolidated metal nanoparticles due to their relatively large size. Particular examples of grain growth inhibitors or precursors thereto suitable for use in the present disclosure are discussed in further detail hereinbelow.

Decreased cracking and void formation during metal nanoparticle consolidation can also be promoted by judicious choice of the solvent(s) forming the organic matrix. A tailored combination of organic solvents can desirably decrease the incidence of cracking and void formation. More particularly, an organic matrix containing one or more hydrocarbons (saturated, monounsaturated, polyunsaturated (2 or more double bonds) or aromatic), one or more alcohols, one or more amines, and one or more organic acids can be especially effective for this purpose. One or more esters and/or one or more anhydrides may be included, in some embodiments. Without being bound by any theory or mechanism, it is believed that this combination of organic solvents can facilitate the removal and sequestration of surfactant molecules surrounding the metal nanoparticles during consolidation, such that the metal nanoparticles can more easily fuse together with one another. More particularly, it is believed that hydrocarbon and alcohol solvents can passively solubilize surfactant molecules released from the metal nanoparticles by Brownian motion and reduce their ability to become re-attached thereto. In concert with the passive solubilization of surfactant molecules, amine and organic acid solvents can actively sequester the surfactant molecules through a chemical interaction such that they are no longer available for recombination with the metal nanoparticles.

Further tailoring of the solvent composition can be performed to reduce the suddenness of volume contraction that takes place during surfactant removal and metal nanoparticle consolidation. Specifically, more than one member of each class of organic solvent (i.e., hydrocarbons, alcohols, amines, and organic acids), can be present in the organic matrix, where the members of each class have boiling points that are separated from one another by a set degree. For example, in some embodiments, the various members of each class can have boiling points that are separated from one another by about 5° C. to about 50° C. or about 20° C. to about 50° C. By using such a solvent mixture, sudden volume changes due to rapid loss of solvent can be minimized during metal nanoparticle consolidation, since the various components of the solvent mixture can be removed gradually over a broad range of boiling points (e.g., about 50° C. to about 200° C.).

In some embodiments, at least some of the one or more organic solvents can have a boiling point of about 100° C. or greater. In some embodiments, at least some of the one or more organic solvents can have a boiling point of about 200° C. or greater. In some embodiments, the one or more organic solvents can have boiling points ranging from about 50° C. to about 250° C. In other embodiments, the one or more organic solvents can have boiling points ranging from about 100° C. to about 350° C. or about 100° C. to about 370° C. Use of high boiling organic solvents can desirably increase the pot life of the metal nanoparticle compositions and limit the rapid loss of solvent, which can lead to cracking and void formation during metal nanoparticle consolidation. In some embodiments, at least one of the organic solvents can have a boiling point that is higher than the boiling point(s) of the surfactant(s) associated with the metal nanoparticles. Accordingly, surfactant(s) can be removed from the metal nanoparticles by evaporation before removal of the organic solvent(s) takes place.

In some embodiments, the organic matrix can contain one or more alcohols. In various embodiments, the alcohols can include monohydric alcohols, diols, triols, glycol ethers (e.g., diethylene glycol and triethylene glycol), alkanolamines (e.g., ethanolamine, triethanolamine, and the like), or any combination thereof. In some embodiments, one or more hydrocarbons can be present in combination with one or more alcohols. As discussed above, it is believed that alcohol and hydrocarbon solvents can passively promote the solubilization of surfactants as they are removed from the metal nanoparticles by Brownian motion and limit their re-association with the metal nanoparticles. Moreover, hydrocarbon and alcohol solvents only weakly coordinate with metal nanoparticles, so they do not simply replace the displaced surfactants in the nanoparticle coordination sphere. Illustrative but non-limiting examples of alcohol and hydrocarbon solvents that can be present include, for example, light aromatic petroleum distillate (CAS 64742-95-6), hydrotreated light petroleum distillates (CAS 64742-47-8), tripropyleneglycol methyl ether, ligroin (CAS 68551-17-7, a mixture of C₁₀-C₁₃ alkanes), diisopropyleneglycol monomethyl ether, diethyleneglycol diethyl ether, 2-propanol, 2-butanol, t-butanol, 1-hexanol, 2-(2-butoxyethoxy)ethanol, and terpineol. In some embodiments, polyketone solvents can be used in a like manner.

In some embodiments, the organic matrix can contain one or more amines and one or more organic acids. In some embodiments, the one or more amines and one or more organic acids can be present in an organic matrix that also includes one or more hydrocarbons and one or more alcohols. As discussed above, it is believed that amines and organic acids can actively sequester surfactants that have been passively solubilized by hydrocarbon and alcohol solvents, thereby making the surfactants unavailable for re-association with the metal nanoparticles. Thus, an organic solvent that contains a combination of one or more hydrocarbons, one or more alcohols, one or more amines, and one or more organic acids can provide synergistic benefits for promoting the consolidation of metal nanoparticles. Illustrative but non-limiting examples of amine solvents that can be present include, for example, tallowamine (CAS 61790-33-8), alkyl (C₈-C₁₈) unsaturated amines (CAS 68037-94-5), di(hydrogenated tallow)amine (CAS 61789-79-5), dialkyl (C₈-C₂₀) amines (CAS 68526-63-6), alkyl (C₁₀-C₁₆)dimethyl amine (CAS 67700-98-5), alkyl (C₁₄-C₁₈) dimethyl amine (CAS 68037-93-4), dihydrogenated tallowmethyl amine (CAS 61788-63-4), and trialkyl (C₆-C₁₂) amines (CAS 68038-01-7). Illustrative but non-limiting examples of organic acid solvents that can be present in the nanoparticle paste compositions include, for example, octanoic acid, nonanoic acid, decanoic acid, caprylic acid, pelargonic acid, undecylic acid, lauric acid, tridecylic acid, myristic acid, pentadecanoic acid, palmitic acid, margaric acid, stearic acid, nonadecylic acid, α-linolenic acid, stearidonic acid, oleic acid, and linoleic acid.

In some embodiments, the organic matrix can include more than one hydrocarbon, more than one alcohol, more than one amine, and more than one organic acid. For example, in some embodiments, each class of organic solvent can have two or more members, or three or more members, or four or more members, or five or more members, or six or more members, or seven or more members, or eight or more members, or nine or more members, or ten or more members. Moreover, the number of members in each class of organic solvent can be the same or different. Particular benefits of using multiple members of each class of organic solvent are described hereinafter.

One particular advantage of using multiple members within each class of organic solvent can include the ability to provide a wide spread of boiling points in the nanoparticle paste compositions. By providing a wide spread of boiling points, the organic solvents can be removed gradually as the temperature rises while affecting metal nanoparticle consolidation, thereby limiting volume contraction and disfavoring cracking. By gradually removing the organic solvent in this manner, less temperature control may be needed to affect slow solvent removal than if a single solvent with a narrow boiling point range was used. In some embodiments, the members within each class of organic solvent can have a window of boiling points ranging between about 50° C. and about 200° C., or between about 50° C. and about 250° C., or between about 100° C. and about 200° C., or between about 100° C. and about 250° C. Higher boiling solvents may be used as well. In more particular embodiments, the various members of each class of organic solvent can each have boiling points that are separated from one another by at least about 5° C., or at least about 10° C., or at least about 20° C., such as about 5° C. to about 25° C., or about 10° C. to about 35° C., or about 20° C. to about 50° C. More specifically, in some embodiments, each hydrocarbon can have a boiling point that differs by about 20° C. to about 50° C. from other hydrocarbons in the organic matrix, each alcohol can have a boiling point that differs by about 20° C. to about 50° C. from other alcohols in the organic matrix, each amine can have a boiling point that differs by about 20° C. to about 50° C. from other amines in the organic matrix, and each organic acid can have a boiling point that differs by about 20° C. to about 50° C. from other organic acids in the organic matrix. The more members of each class of organic solvent that are present, the smaller the differences become between the boiling points. By having smaller differences between the boiling points, solvent removal can be made more continual, thereby limiting the degree of volume contraction that occurs at each stage. A reduced degree of cracking can occur when four to five or more members of each class of organic solvent are present (e.g., four or more hydrocarbons, four or more alcohols, four or more amines, and four or more organic acids; or five or more hydrocarbons, five or more alcohols, five or more amines, and five or more organic acids), each having boiling points that are separated from one another within the above range.

In addition to discouraging cracking with the solvent content of the metal nanoparticle composition, the silicate-reactive matrix material, when used in the disclosure herein, may adhere the via fill material to the via walls and/or the seed layer to the substrate surface. Adherence, preferably through chemical bonding, to these surfaces may further suppress cracking following metal nanoparticle consolidation and during thermal cycling of the substrates during use.

In various embodiments, the metal nanoparticles used in the nanoparticle paste compositions can be about 20 nm or less in size. In some embodiments, suitable metal nanoparticles may be up to about 75 nm in size, up to about 100 nm in size, up to about 150 nm in size, or even up to about 200 nm in size. As discussed above, metal nanoparticles in a size range of about 20 nm or below may have fusion temperatures that are significantly lower than those of the corresponding bulk metal and readily undergo consolidation with one another as a result. Accordingly, in at least some embodiments, metal nanoparticles about 20 nm or less in size may be combined with metal nanoparticles that are 20 nm or above in size to promote tailoring of the fusion temperature. In some embodiments, metal nanoparticles that are about 20 nm or less in size can have a fusion temperature of about 220° C. or below (e.g., a fusion temperature in the range of about 140° C. to about 220° C.) or about 200° C. or below, which can provide advantages that are noted above. In some embodiments, at least a portion of the metal nanoparticles can be about 10 nm or less in size, or about 5 nm or less in size. In some embodiments, at least a portion of the metal nanoparticles can range between about 1 nm in size to about 20 nm in size, or between about 1 nm in size and about 10 nm in size, or between about 1 nm in size to about 5 nm in size, or between about 3 nm in size to about 7 nm in size, or between about 5 nm in size to about 20 nm in size. Any of the foregoing size ranges may be combined with metal nanoparticles about 30 nm or larger in size, or about 50 nm or larger in size, or about 75 nm or larger in size, or about 100 nm or larger in size, or about 150 nm or larger in size. In some embodiments, substantially all of the metal nanoparticles can reside within these size ranges. In some embodiments, larger metal nanoparticles can be combined in the metal nanoparticle compositions with metal nanoparticles that are about 20 nm in size or less. For example, in some embodiments, metal nanoparticles ranging from about 1 nm to about 10 nm in size or about 5 nm to about 20 nm in size can be combined with metal nanoparticles that range from about 25 nm to about 50 nm in size, or with metal nanoparticles that range from about 25 nm to about 100 nm in size, or about 30 nm to about 80 nm in size. In other embodiments, smaller metal nanoparticles need not necessarily be present, and the metal nanoparticles may be about 30 nm or larger in size, or about 50 nm or larger in size, or about 75 nm or larger in size, or about 100 nm or larger in size, or about 150 nm or larger in size, such as within a size range of about 30 nm to about 100 nm, or about 75 nm to about 150 nm, or about 125 nm to about 200 nm. More efficient packing of the metal nanoparticles during consolidation may be realized by using metal nanoparticles in two different size ranges. As further discussed below, micron-size metal particles or nanoscale particles can also be included in the metal nanoparticle compositions in some embodiments. Although larger metal nanoparticles and micron-size metal particles may not be liquefiable at the low temperatures of their smaller counterparts, they can still become consolidated upon contacting the smaller metal nanoparticles that have formed a liquid-like state at or above their fusion temperature, as generally discussed above. When smaller metal nanoparticles and larger metal nanoparticles are used in combination with one another, the smaller and larger metal nanoparticles may be combined in any ratio.

In addition to metal nanoparticles and organic solvents, other additives can also be present in the nanoparticle paste compositions. Such additional additives can include, for example, rheology control aids, thickening agents, micron-size conductive additives, nanoscale conductive additives, CTE modifiers, and any combination thereof. Chemical additives can also be present. As discussed hereinafter, the inclusion of micron-size conductive additives, such as micron-size metal particles, can be particularly advantageous. Nanoscale or micron-size diamond or other thermally conductive additives may be desirable to include in some instances. The additional additives may be included in various amounts and combinations to alter the viscosity properties of the metal nanoparticle compositions to support dispensation of the metal nanoparticle compositions in a given location and by a specified technique. For example, metal nanoparticle compositions for via filling may have a lower viscosity than do those applied to a substrate surface to form a conductive trace.

In some embodiments, the metal nanoparticle compositions can contain about 0.01% to about 15% micron-size metal particles by weight, or about 1% to about 10% micron-size metal particles by weight, or about 1% to about 5% micron-size metal particles by weight. Micron-size metal particles can also be present in the metal nanoparticle compositions in an amount of about 10% to about 35% by weight, or about 15% to about 35% by weight, or about 20% to about 35% by weight, or about 25% to about 35% by weight. Inclusion of micron-size metal particles in the metal nanoparticle compositions can desirably reduce the incidence of cracking that occurs during consolidation of the metal nanoparticles when forming a metallization layer or conductive trace in the disclosure herein. Without being bound by any theory or mechanism, it is believed that the micron-size metal particles can become consolidated with one another as the metal nanoparticles form a liquid-like state and form a transient liquid coating upon the micron-size metal particles. In some embodiments, the micron-size metal particles can range between about 500 nm to about 100 microns in size in at least one dimension, or from about 500 nm to about 10 microns in size in at least one dimension, or from about 100 nm to about 5 microns in size in at least one dimension, or from about 100 nm to about 10 microns in size in at least one dimension, or from about 100 nm to about 1 micron in size in at least one dimension, or from about 1 micron to about 10 microns in size in at least one dimension, or from about 5 microns to about 10 microns in size in at least one dimension, or from about 1 micron to about 100 microns in size in at least one dimension. The micron-size metal particles can contain the same metal as the metal nanoparticles or contain a different metal. Thus, metal alloys can be fabricated by including micron-size metal particles in the metal nanoparticle compositions with a metal differing from that of the metal nanoparticles. Suitable micron-size metal particles can include, for example, Cu, Ni, Al, Fe, Co, Mo, Ag, Zn, Sn, Au, Pd, Pt, Ru, Mn, Cr, Ti, V, Mg or Ca particles. Non-metal particles such as, for example, Si and B micron-size particles can be used in a like manner. In some embodiments, the micron-size metal particles can be in the form of metal flakes, such as high aspect ratio copper flakes, for example. That is, in some embodiments, the metal nanoparticle compositions described herein can contain a mixture of copper nanoparticles and high aspect ratio copper flakes or a mixture of copper nanoparticles and other micron-size copper particles. Specifically, in some embodiments, the metal nanoparticle compositions can contain about 30% to about 97% copper nanoparticles by weight and about 0.01% to about 15% or about 0.01% to about 30% high aspect ratio copper flakes or other micron-size copper particles by weight. The high aspect ratio copper flakes may be in nanoparticle form, according to some embodiments.

Other micron-size metal particles that can be used equivalently to high aspect ratio metal flakes include, for example, metal nanowires and other high aspect ratio particles, which can be up to about 300 microns in length. The ratio of metal nanoparticle to metal nanowires may range between about 10:1 to about 40:1, according to various embodiments. Suitable nanowires may have a length of between about 5 microns and about 50 microns, and a diameter between about 100 nm and about 200 nm, for example.

In some embodiments, nanoscale conductive additives can also be present in the metal nanoparticle compositions. These additives can desirably provide further structural reinforcement and reduce shrinkage during metal nanoparticle consolidation. Moreover, inclusion of nanoscale conductive additives can increase electrical and thermal conductivity values that can approach or even exceed that of the corresponding bulk metal following nanoparticle consolidation. In some embodiments, the nanoscale conductive additives can have a size in at least one dimension ranging between about 1 micron and about 100 microns, or ranging between about 1 micron and about 300 microns. Suitable nanoscale conductive additives can include, for example, carbon nanotubes, graphene, other graphite-type materials, and the like. When present, the metal nanoparticle compositions can contain about 1% to about 16% nanoscale conductive additives by weight, or about 1% to about 10% nanoscale additives by weight, or about 1% to about 5% nanoscale conductive additives by weight.

Additional substances that can also optionally be present in the metal nanoparticle compositions include, for example, flame retardants, UV protective agents, antioxidants, carbon black, graphite, fiber materials (e.g., chopped carbon fiber materials), diamond, cubic BN, and the like.

Metal nanoparticle compositions suitable for use in the present disclosure can be formulated using any of the formulations described hereinabove, including those in which a grain growth inhibitor is further included, particularly a grain growth inhibitor comprising a metal. The grain growth inhibitor may be included in a suitable form such that the grain growth inhibitor is capable of entering grain boundaries following nanoparticle consolidation. If not included in a suitable form, ineffective grain growth inhibition may occur, even if the grain growth inhibitor otherwise comprises a substance that is capable of providing grain growth inhibition.

In particular embodiments, metal nanoparticle compositions suitable for use in the disclosure herein may comprise copper nanoparticles and a suitable amount of a grain growth inhibitor to prevent substantial grain growth upon heating of a bulk copper matrix formed from the copper nanoparticles. Various CTE modifiers may be present as well. The suitable amount of the grain growth inhibitor and/or CTE modifier may range from about 0.01 wt. % to about 15 wt. % of the composition, according to various embodiments. Effective temperature ranges over which the grain growth inhibitor may inhibit grain growth are considered below.

Suitable grain growth inhibitors may be metal particles that are insoluble in a copper matrix. Suitable grain growth inhibitors may be foreign nanoparticles that are in the 25 nm and under size range or about 10 nm and under size range. Grain growth inhibitors comprising a metal, particularly metal nanoparticles having a size of about 25 nm or under or about 10 nm or under, may be particularly desirable for inclusion in a bulk copper matrix. The small nanoparticle size allows the grain growth inhibitors to access the grain boundaries readily. Inclusion of the grain growth inhibitors limits grain growth by interface or Zener pinning and ensures that the nano-grain structure is retained even after prolonged exposure to high temperatures, frequent temperature cycling, and thermal shock. These actions may prevent further atom diffusion and reorganization.

Suitable metals for a grain growth inhibitor may include, for example, Fe, Mn, Cr, Co, Ru, Si, V, W, Nb, Ta, Y, Zr, Hf, Be, TI, Rh, Ir, Ti, Mo, Re, Al, alloys thereof, or any combination thereof, particularly nanoparticles comprising one or more of these metals. Si is considered to be a metal for purposes of the present disclosure. The metal particles may be metal nanoparticles or micron-size metal particles, according to various embodiments. Nanoparticles of these metals may be particularly suitable. Other suitable grain growth inhibitors may include, for example, carbides, nitrides, borides, silicides, or phosphides. Suitable borides may include, for example, Zr/Hf, V, or Nb/Ta. Similar metals may be appropriate for carbides, nitrides, silicides and phosphides, although any of the metals above may be suitable. Other suitable phosphides may include covalent phosphides such as BP and SiP₂, transition metal phosphides such as Fe₃P, Fe₂P, Ni₂P, CrP, MnP, MoP and the like. Metal-rich phosphides such as these may be desirable due to their water insolubility, electrical conductivity, high melting points, thermal stability, hardness, and similar properties. Other suitable carbides may include covalent carbides such as BC (including BₓC_{y} non-stoichiometric carbides) and SiC, and transition metal carbides, which similarly exhibit high melting points, hardness, electrical conductivity, and similar properties. Graphene and other nanocarbon materials may also be effective grain growth inhibitors in some cases.

Suitable grain growth inhibitors may be included in copper nanoparticle paste compositions in an amount ranging between about 0.01 wt. % to about 15 wt. % with respect to the composition or in a bulk copper matrix resulting therefrom. In more particular embodiments, the grain growth inhibitors may be present in an amount ranging between about 0.01 wt. % and about 5 wt. %, or between about 0.1 wt. % and about 0.5 wt. %. Particular copper nanoparticle compositions may comprise up to about 12 wt. % Al, or about 0.01-5 wt. % Zr, or 0.01-5 wt. % Zr/Hf. These particular grain growth inhibitors in the referenced amounts may provide temperature stability of up to about 940° C., 500° C. or 600° C., respectively. Aluminum may be advantageous for forming insoluble binary phases like CuAl₂ or Cu₉Al₄. Al₂O₃, including nanoparticles thereof, may also be a suitable grain growth inhibitor and may also impart enhanced oxidation resistance.

The grain growth inhibitors may be in various forms when incorporated/combined with the copper nanoparticles. In some embodiments, the grain growth inhibitors may be nanoparticles themselves, particularly having a size of about 25 nm or less or about 10 nm or less. In other embodiments, the grain growth inhibitors may range between 10 nm and 100 nm in size or between about 25 nm and about 100 nm in size.

When incorporated as nanoparticles, reagents for forming the grain growth inhibitors may be mixed with the reagents for forming the copper nanoparticles (or other types of metal nanoparticles) and then they may undergo co-reduction to form the copper nanoparticles and the grain growth inhibitors simultaneously. Suitable reagents for forming the grain growth inhibitors may include, for example, metal nitrates, chloride, bromides or iodides. The grain growth inhibitors may also constitute nanoparticle seeds for the copper nanoparticles (or other metal nanoparticles), and then become incorporated within the resulting bulk copper matrix following copper nanoparticle fusion. Nanoparticle seeds suitable for becoming a grain growth inhibitor may be made separately and combined with the reagents for forming the copper nanoparticles, or such nanoparticle seeds may be formed concurrently with forming the copper nanoparticles. Carrier solvents may be used to disperse the reagents for forming the nanoparticle seeds/grain growth inhibitors before dispersal with the copper nanoparticles or precursors to the copper nanoparticles.

Alternately, preformed grain growth inhibitors may be mixed with preformed copper nanoparticles (or other metal nanoparticles), either before or after formulating the copper nanoparticles into a metal nanoparticle composition.

In still other alternative embodiments, a trialkylaluminum compound (e.g., trimethylaluminum) may be incorporated in the metal nanoparticle compositions. The trialkylaluminum may react during copper nanoparticle consolidation to release aluminum or an aluminum compound into the grain boundaries.

Still further alternately, salts that form the grain growth inhibitors following reduction may be mixed within the metal nanoparticle compositions and then undergo reduction to form the grain growth inhibitors during consolidation of the metal nanoparticles. Carrier solvents may be used to promote mixing with the metal nanoparticle compositions.

In still other embodiments, NaReO₄ may be formulated into a grain growth inhibitor. This salt is compatible with both aqueous and non-aqueous solvent conditions (including glyme solvent mixtures) and the same amines that may be used in forming copper nanoparticles. Reducing agents such as NaBH₄, CaH₂, hydrazine, organomagnesium or organosodium compounds, or redAl may be used to affect reduction.

CTE adjustment in the metal nanoparticle compositions or metallization layers resulting therefrom may be accomplished by adding low CTE materials in the form of small particles (e.g., platelets, fibers, wires, and the like in the 0.5-250 micron range) to the metal nanoparticle compositions. Examples include, but are not limited to, diamond, BN, SiC, AlN, graphite, carbon nanotubes, graphene, and the like. Preferably, CTE adjustment may be accomplished with materials having high thermal conductivity, but silica and other oxides with negative thermal expansion may be suitable as well. The addition of micron-size metal particles allows the adjustment upwards. High aspect ratio particles may further help increase mechanical strength. The metal nanoparticle compositions introduced into the via and those used to form the metallization layer may be the same or different in composition and may or may not comprise the same metals. CTE adjustment, also referred to as CTE matching in the disclosure herein, may refer to two CTE values differing from one another by not more than about 20%, not more than about 15%, not more than about 10%, not more than about 5%, or not more than about 1%.

Accordingly, the present disclosure provides metallized substrates, which may define interposers for incorporation in an electronic component or located elsewhere in an electrical interconnect. The metallized substrates comprise: a base substrate having one or more vias terminating in the base substrate (blind vias), extending between a first face and a second face of the base substrate (through-plane vias), or any combination thereof, the base substrate comprising a glass substrate or a silicon substrate; and a via fill material within the one or more vias. The via fill material comprises: 1) a porous matrix material having a void space of about 30% to about 60% and comprising a plurality of electrically conductive particles optionally bonded together with a cured silicate-reactive matrix material; and 2) a conductive network at least partially filling the void space within the porous matrix material, the conductive network comprising a plurality of metal nanoparticles that have been consolidated with one another.

Base substrates suitable for use in the present disclosure may be silicon or glass. When used, the silicate-reactive matrix material may form a chemical bond to the glass or silicon substrate (e.g., with the via walls and/or one or more of the faces of the substrate) upon curing to promote the features described herein.

The vias within the base substrate may be up to about 100 microns in diameter or even up to about 250 microns in diameter or up to about 500 microns in diameter, or be as small as about 5 microns or about 10 microns in diameter. Thus, vias within the base substrate, in non-limiting examples, may range from about 5 microns to about 500 microns in diameter, or about 10 microns to about 150 microns in diameter, or about 10 microns to about 50 microns in diameter, or about 50 microns to about 100 microns in diameter, or about 100 microns to about 150 microns in diameter, or about 150 microns to about 250 microns in diameter, or about 250 microns to about 500 microns in diameter, or about 5 microns to about 25 microns in diameter, or about 25 microns to about 75 microns in diameter, or about 75 microns to about 125 microns in diameter, or about 75 microns to about 175 microns in diameter. Suitable vias may have any cross-sectional profile as they extend through the base substrate. According to some embodiments, the vias may have a round cross-sectional profile; thus, such vias have a cylindrical shape. Other suitable via cross-sectional profiles include, but are not limited to, square, rectangular, triangular, ovular, or other regular or irregular geometric shapes. The cross-sectional profile of the vias may be substantially equal in size upon both faces of the substrate, or the cross-sectional profiles may differ in size, according to some embodiments. That is, the vias may be tapered, in some embodiments. In some embodiments, suitable vias may taper from a larger diameter to a smaller diameter from the surface of the substrate to the interior of the substrate, optionally wherein the tapered via has a substantially equal diameter upon each face of the base substrate. Both blind vias and through-plane vias may be loaded with the via fill material and the conductive network in the disclosure herein.

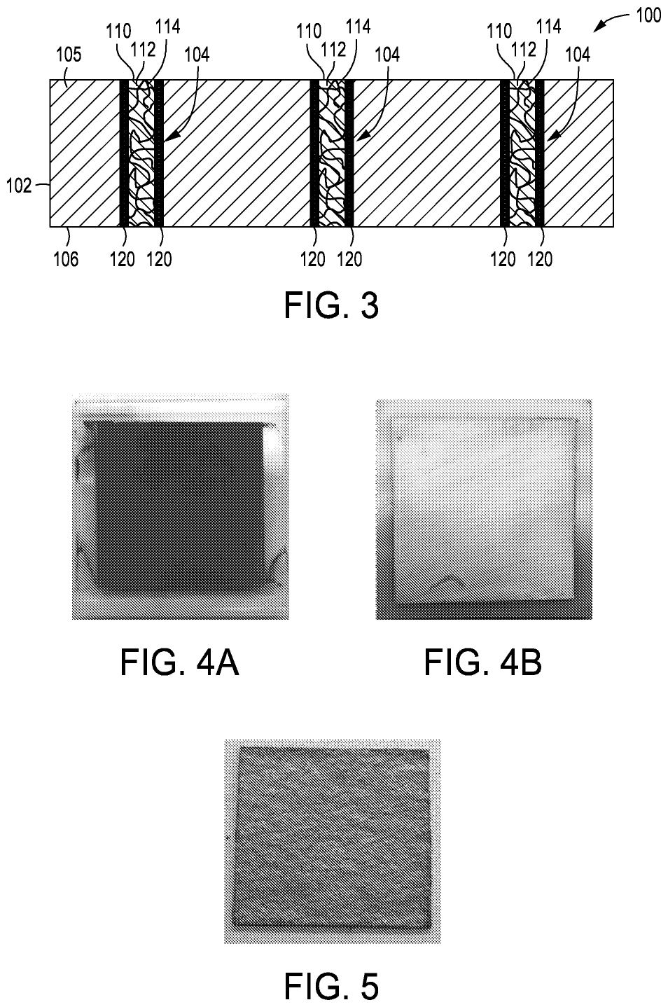

FIG. 3 is a diagram of a metallized substrate of the present disclosure containing filled vias. As shown, metallized substrate 100 includes base substrate 102 having vias 104 extending between upper face 105 and lower face 106. Vias 104 are loaded with via fill material 110, which comprises porous matrix material 112 and conductive network 114 comprising consolidated metal nanoparticles. Conductive network 114 is located within the void space of porous matrix material 112. Porous matrix material 112 comprises a plurality of electrically conductive particles (e.g., micron-size metal particles). Optionally, porous matrix material 112 may further comprise a cured silicate-reactive matrix material that bonds the micron-size metal particles together. Upon curing, the cured silicate-reactive matrix material may form surface coating 120 through covalent bonding upon the walls of vias 104, thereby affording hermetic sealing thereof. Moreover, when used, the cured silicate-reactive matrix material may robustly adhere the electrically conductive particles together and promote retention of via fill material 110 within vias 104. Even when the walls of vias 104 are not hermetically sealed and the plurality of electrically conductive particles are not bonded together using a cured silicate-reactive matrix material, suitable electrical conductivity and/or thermal conductivity of vias 104 may still be realized. Although vias 104 in FIG. 3 are shown as through-plane vias, it is to be appreciated that blind vias may be similarly filled.

The via fill material may be CTE matched to the base substrate by way of CTE-matching the metal nanoparticle composition from which the conductive network is formed.

When used, the cured silicate-reactive matrix material may be formed by depositing a liquid formulation comprising an uncured silicate-reactive substance and a plurality of electrically conductive particles. The liquid formulation may comprise a liquid glass binder, and the porous matrix material may comprise the electrically conductive particles bonded together with cured liquid glass binder. Suitable liquid glass binders may comprise sodium or potassium silicate in a 40-70% aqueous solution (w/w), optionally including a base (e.g., NaOH, KOH, Ca(OH)₂ or the like) and/or 50 nm-3 micron alumina particles. The silicate concentration in the aqueous solution may be in the 2-50% range by weight, or 2-15% range by weight, or 5-20% range by weight, or 10-30% range by weight, or 15-50% range by weight. Organosilanes or organosilanols may also be suitable in this regard.

Optionally, the liquid formulation used for via filling may further comprise an additive that improves compatibility between the matrix material and the electrically conductive particles therein, such as through promoting covalent bond formation between the two. The increased interaction between the electrically conductive particles and the matrix material may promote more robust adherence of the electrically conductive particles to each other and also aid in preventing cracking and other modes of mechanical failure. In some embodiments, the additive may comprise an amino group that may react with a surface of the electrically conductive particles and a silane group that may react with the matrix material. That is, the additive may serve as a bridging group between the electrically conductive particles (or the via walls) and the cured silicate-reactive matrix material. Suitable additives therefore include aminoalkyldialkoxysilanes, aminoalkyltrialkoxysilanes, or any combination thereof. Aminopropyltriethoxysilane (APTES) is a non-limiting example of a suitable additive that may be present.

Examples of electrically conductive particles that may be present in a liquid formulation that is introduced into the one or more vias to form the porous matrix material are not believed to be especially limited. Illustrative examples may include metal particles (including micron-size metal particles, metal powder, or any combination thereof), chopped metal wires, metal nanowires, carbon nanotubes, graphene, other types of carbon nanomaterials, or any combination thereof. The electrically conductive particles may have a maximum diameter that is no larger than about 1/10^{th} a diameter of the one or more vias. For elongated electrically conductive particles, such as metal nanowires, carbon nanotubes, graphene, and other carbon nanomaterials, a length of the electrically conductive particles may be no larger than about ¾^{th} of the diameter of the one or more vias. It may be desirable to introduce at least some elongated electrically conductive particles when filling the via due to the scaffolding effect they may provide as a consequence of their high aspect ratio. In non-limiting examples, elongated electrically conductive particles may be present in an amount up to about 67 vol. % of the via. In more specific examples, the elongated electrically conductive particles may have a length ranging from about 100 nm to about 5 microns or about 100 nm to about 3 microns, and a diameter ranging from about 50 nm to about 200 nm. Thus, according to some embodiments, the conductive network with the vias may comprise a mixture of micron-size metal particles and one or more elongated electrically conductive particles. Metal nanoparticles may then fill the void volume within the resulting conductive network.

Examples of suitable metals within the micron-scale metal particles, metal wires, metal wires or other types of metal-containing materials may include, but are not limited to, copper, aluminum, silver, gold, palladium, tungsten, and any combination thereof. In various embodiments, the via fill material may comprise at least copper, for example, at least micron-scale copper particles. The foregoing metals, or any other metals mentioned herein as being suitable to form metal nanoparticles, may be present in the metal nanoparticles introduced to form the conductive network within the via fill material. In non-limiting examples, the conductive network may comprise a copper network formed from copper nanoparticles.

When used, the silicate-reactive matrix material may be present in a least a sufficient amount to bond the electrically conductive particles together and promote retention of the via fill material within the one or more vias. In non-limiting examples, a mass ratio of the electrically conductive particles to cured silicate-reactive matrix material in the via fill material may range from about 4:1 to about 30:1, or about 6:1 to about 30:1, or about 8:1 to about 25:1, or about 10:1 to about 20:1, or about 15:1 to about 25:1. The silicate-reactive matrix material may further react with the via walls to promote hermetic sealing thereof and to facilitate retention of the via fill material within the via.

Methods for filling vias according to the disclosure herein may comprise: providing a base substrate having one or more vias defined therein, the one or more vias terminating in the base substrate, extending between a first face and a second face of the base substrate, or any combination thereof, and the base substrate comprising a glass substrate or a silicon substrate; depositing a via fill precursor comprising a plurality of electrically conductive particles and optionally a silicate-reactive matrix material within the one or more vias; curing the via fill precursor to form a porous matrix material having a void space of about 30% to about 60%; introducing a metal nanoparticle composition into at least a portion of the void space; and at least partially consolidating metal nanoparticles of the metal nanoparticle composition with one another in the void space to form a conductive network at least partially filling the void space. Curing may include sintering of the electrically conductive particles and, when present, converting the silicate-reactive matrix material into a cured silicate-reactive matrix material that at least bonds the electrically conductive particles together.

Introduction of the metal nanoparticle composition into the void space of the via fill material may take place by any suitable technique compatible with at least partially filling the void space, preferably filling at least about 90%, or at least about 95%, or at least about 99% of the void space. Suitable techniques may include pressure infiltration, vacuum infiltration, or any combination thereof. Conditions for infiltrating the metal nanoparticle compositions may further promote consolidation of the metal nanoparticles to form the conductive network in the void space. In non-limiting examples, conditions within the vacuum infiltration and/or pressure infiltration process may include a temperature of about 200° C. to about 270° C. and a pressure of about 500 psi to about 2500 psi. The via fill precursor and the metal nanoparticle composition may be combined together prior to being deposited and introduced into the one or more vias, and/or the via fill precursor and the metal nanoparticle composition may be deposited and introduced separately into the one or more vias.

In addition to the filled vias discussed above, the metallized substrates disclosed herein may further comprise one or more conductive traces defined upon at least one of the first face or the second face of the base substrate and in electrical communication with the via fill material within the one or more vias. The one or more conductive traces may be deposited upon a seed layer adhered to at least one of the first face or the second face, and wherein the seed layer comprises a cured silicate-reactive matrix material and a second plurality of electrically conductive particles mixed with the cured silicate-reactive matrix material. The seed layer may be electrically non-conductive or have low conductivity as-deposited and subsequently be rendered electrically conductive through mechanical polishing, as discussed in further detail hereinafter. The conductive traces may be located upon the seed layer, preferably after the seed layer has been converted to an electrically conductive state. The seed layer may be considered to define part of the electrically conductive traces formed thereon. Thus, it is preferable for the seed layer to be electrically conductive. Moreover, once the seed layer has been mechanically polished, increased adherence of a metallization layer thereon may be realized, wherein the metallization layer may be subsequently refined to form one or more conductive traces in a desired location.

The conductive traces may further be in direct electrical communication with the via fill material or in indirect electrical communication by way of a bonding pad deposited upon the via fill material. The seed layer may be deposited as a discontinuous layer to accommodate direct or indirect contact between the conductive traces and the vias, as explained in further detail hereinbelow.

Advantageously, a coating formulation deposited upon one or more faces of the base substrate to form a seed layer thereon may comprise a similar type of formulation to that used for forming the porous matrix material in the one or more vias, at least when the via fill material also comprises a silicate-reactive matrix material that undergoes curing to form a cured silicate-reactive matrix material. Namely, the coating formulation for an exterior surface of the base substrate may also comprise a plurality of electrically conductive particles (e.g., a plurality of micron-size metal particles) and a silicate-reactive matrix material, which may be the same as or different than the silicate-reactive matrix material used to form the porous matrix material in the one or more vias. The second plurality of electrically conductive particles within the coating formulation applied to an exterior surface of the base substrate may be a plurality of micron-size metal particles, such as copper particles or copper powder. Curing forms the seed layer by converting the silicate-reactive matrix material from an initially fluid state into a substantially non-fluid state, which is bonded to the surface of the base substrate and physically adheres the electrically conductive particles to each other and to the surface of the base substrate.

Optionally, the coating formulation may further comprise an additive that improves compatibility between the matrix material of the seed layer and the metal particles therein, such as through promoting covalent bond formation between the two, as discussed above. The increased interaction between the metal particles and the matrix material may help prevent cracking under thermal stress. In some embodiments, the additive may comprise an amino group that may react with a surface of the metal particles and a silane group that may react with the matrix material. Suitable additives therefore include aminoalkyldialkoxysilanes, aminoalkyltrialkoxysilanes, or any combination thereof. Aminopropyltriethoxysilane (APTES) is a non-limiting example of a suitable additive that may be present.

Suitable techniques for applying the coating formulation to an exterior surface of the base substrate are not believed to be particularly limited and may include techniques such as, but not limited to, spray on, brush on, dip coating, ink jet printing, stenciling, spin-on coating, or similar application techniques. Unless otherwise indicated, all or a substantial portion of the exterior surface of the base substrate may be coated with the coating formulation when forming a seed layer. The viscosity of the coating formulation may be tailored to support a chosen deposition technique. Deposition of the coating formulation upon the exterior of the base substrate may take place after filling of the one or more vias takes place according to the disclosure herein. The seed layer may be deposited selectively to avoid overcoating the one or more vias, or an opening may be defined within the seed layer to expose the via fill material for promoting electrical communication with a conductive trace.

Metal particles (e.g., micron-size metal particles and/or metal nanoparticles) within the coating formulation may comprise the same metal or a different metal than in a metallization layer subsequently formed on the seed layer produced upon curing the coating formulation. The metal within the metallization layer may comprise a metal chosen from any of the metal nanoparticle types referenced above, and metal particles within the coating formulation/seed layer may be selected to match or differ from the metal within the metallization layer. For example, the metal particles within the coating formulation/seed layer and the metal within the metallization layer may both comprise copper. The metal within the coating formulation/seed layer and the metal within the metallization layer may be the same as or different than a metal within the one or more vias. However, copper may be present in all three locations in various embodiments.

The amount of silicate-reactive matrix material to electrically conductive particles, such as micron-size metal particles, in the coating formulation may vary over a wide range. The chosen range may be selected such that the coating formulation may be dispensed by a specified application technique, since viscosity of the coating formulation may vary with the electrically conductive particle loading. In non-limiting examples, a mass ratio of the electrically conductive particles to the silicate-reactive matrix material in the coating formulation or seed layer may range from about 1:1 to about 30:1, or about 2:1 to about 10:1, or about 3:1 to about 6:1, 6:1 to about 12:1, or about 12:1 to about 20:1, or about 15:1 to about 30:1.

The layer thicknesses of the seed layer after curing may vary over a range of values and may depend upon the size of electrically conductive particles, such as metal particles, present therein. In non-limiting examples, the seed layer may range from about 1 micron to about 50 microns in thickness, or about 1 micron to about 30 microns in thickness, or about 1 micron to about 20 microns in thickness, or about 5 microns to about 30 microns in thickness, or about 1 micron to about 10 microns in thickness. The diameter of the electrically conductive particles, such as metal particles, may determine the thickness of the seed layer, at least in part. Seed layer thicknesses in the 5-20 micron or 10-30 micron size range may be realized with metal particles having a size of about 1-5 microns, or about 10-12 microns, or about 10-28 microns. Even thicker seed layers may be realized by applying the coating formulation to the substrate multiple times and/or using larger metal particles therein.

The initially deposited seed layer (after curing) may be an electrical insulator or have low electrical conductivity due to the electrically conductive particles, such as metal particles, being unconnected or minimally connected with one another. Surprisingly, the seed layer may be converted from an electrical insulator state to an electrical conductor state by mechanical polishing after deposition and curing have taken place. Suitable mechanical polishing may be accomplished by rubbing the seed layer with an abrasive material like sandpaper or steel wool. In another example, chemical-mechanical polishing processes commonly used in the electronics industry may be used as an alternative. Without being bound by theory or mechanism, the mechanical polishing process is believed to promote smearing of the grains of metal particles within the seed layer and establishing interconnectivity in between.

In addition to promoting electrical conductivity, the physical appearance of the seed layer may be altered following the mechanical polishing operation. For example, FIGS. 4A and 4B are images of a glass substrate coated with a seed layer containing copper particles before and after polishing, respectively. The initially dull appearance of the seed layer becomes much shinier following polishing. FIG. 5 is an image of a metallized glass substrate, which may be prepared as described in further detail below. The glass substrate in FIGS. 4A, 4B, and 5 does not have vias defined therein and has been presented to highlight the deposition of a seed layer and metallization layer upon the substrate surface. The metallization layer in FIG. 5 is formed upon a seed layer, as described in more detail above.

Sheet resistivity values within the seed layer after mechanical polishing may be about 500 mOhm/sq or less, or about 400 mOhm/sq or less, or about 300 mOhm/sq or less, or about 200 mOhm/sq or less, or about 100 mOhm/sq for seed layer thicknesses of about 30 microns or higher. At 10 microns or less in thickness, the sheet resistivity may range from about 1 Ohm/sq to about 10 Ohm/sq. A copper-containing seed layer having a sheet resistivity of about 100 mOhm/sq is still about 100 times higher than that of bulk copper but still considerably more conductive than conventional materials without mechanical polishing being performed. Such conductivity/resistivity values are still sufficient to establish electrical communication between conductive traces deposited upon the seed layer and the via fill material.

In non-limiting examples, the metallization layer deposited upon the seed layer after mechanical polishing of the latter may have a sheet resistivity of about 1 mOhm/sq or below, or about 0.5 mOhm/sq, or about 0.25 mOhm/sq. For example, a copper-based metallization layer may have a sheet resistivity of about 0.15 mOhm/sq for a 300 micron thick layer, and a sheet resistivity of about 0.05 mOhm/sq for a 650 micron thick layer.

Advantageously, the coating formulations used herein may be applied without taking inert atmosphere precautions. In non-limiting examples, sufficient curing of liquid glass matrices (when present in the form of a silicate-reactive matrix material) may take place at temperatures up to about 100° C., such as about 90° C. to about 100° C. over approximately a 10-15 minute curing time or even as low as room temperature. Similar advantages apply to the materials introduced in forming the via fill material.

After mechanical polishing (optionally and preferably such that the seed layer is rendered electrically conductive), a metallization layer may be deposited thereupon using a metal nanoparticle composition. The metal nanoparticle composition may be formulated to facilitate a selected deposition method, ranging from low-viscosity dispersions compatible for spraying, printing, stenciling, or similar applications, to thick pastes for brush-on, doctor blading, or wipe-on type applications for depositing thicker metal layers. The metallization layer may be a continuous metallization layer, similar to a bulk copper sheet adhered to the base substrate via the seed layer (analogous to a copper sheet adhered to a glass fiber substrate via an adhesive), or conductive traces may be directly printed in a desired pattern upon the seed layer using the metal nanoparticle composition. Selective etching of a continuous metallization layer may provide metal traces upon a surface of the substrate, if conductive traces have not been printed directly. As indicated above, metal nanoparticle compositions suitable for the foregoing may further feature CTE matching with the substrate being coated according to the disclosure herein. Moreover, as an alternative, conventional electroplating or electroless plating techniques may be utilized for forming a continuous metallization layer as well, which may be subsequently etched to define one or more conductive traces upon the surface of the substrate.

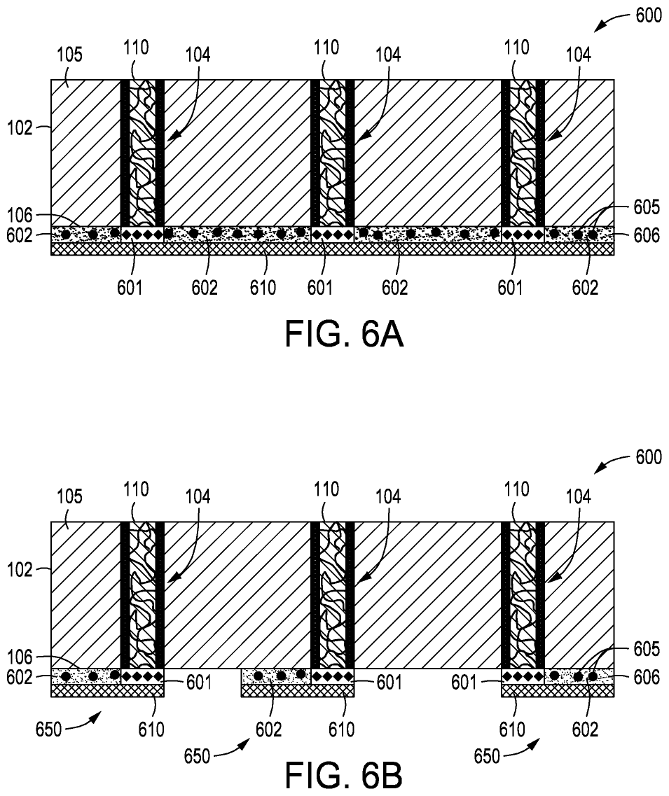

FIG. 6A is a diagram of a metallized substrate of the present disclosure further having a seed layer and a continuous metallization layer disposed thereon. Metallized substrate 600, other than having bonding pads 601, seed layer 602 and metallization layer 610 thereon is otherwise similar to metallized substrate 100 in FIG. 3 and may be better understood by reference thereto. Common reference characters will be used to describe elements within metallized substrate 600 have substantial similarity to a corresponding element in FIG. 3. Although vias 104 in FIG. 6A are shown as through-plane vias, the concepts disclosed therein are also applicable to blind vias. As shown, metallized substrate 600 includes base substrate 102 having vias 104 filled as described above and seed layer 602 disposed upon at least a portion of base substrate 102. Seed layer 602 includes matrix material 606 and metal particles 605 therein. Prior to deposition of seed layer 602, bonding pads 601 may be disposed upon the outer surface of vias 104. Bonding pads 601 may comprise the same metal nanoparticle composition as that used to deposit metallization layer 610, or the metal nanoparticle composition may be different. Seed layer 602 may then be deposited upon the surface of base substrate 102 such that seed layer 602 is contiguous with bonding pads 601 but is otherwise discontinuous. Alternately, seed layer 602 may be deposited as a continuous layer covering vias 104, and openings within seed layer 602 to expose vias 104 may be defined through selective etching or grinding of seed layer 602. In this case, bonding pads 601 and metallization layer 610 may be formed simultaneously, and bonding pads 601 need not necessarily be distinguishable from metallization layer 610. That is, when vias 104 are exposed, metallization layer 610 may be deposited directly upon vias 104 and upon seed layer 602, such that discrete bonding pads 601 are not present. Metallization layer 610, preferably formed from a metal nanoparticle composition, is deposited upon bonding pads 601 (or vias 104) and at least a portion of seed layer 602 and may be CTE-matched thereto or to base substrate 102. Metallization layer 610 is in electrical communication with via fill material 110 by way of bonding pads 601. Metallization layer 610 may comprise direct printed conductive traces, or a continuous metallization layer that is subsequently etched away to define one or more conductive traces in electrical communication with via fill material 110 by way of bonding pads 601 (or directly if bonding pads 601 are not discrete from metallization layer 610). Although seed layer 602 and metallization layer 610 have been shown as having a sharp interface between the two, it is to be appreciated that at least partial mixing between seed layer 602 and metallization layer 610 may occur, such that there is about a 1-10 micron mixing zone between the two.

FIG. 6B is a diagram of metallized substrate 600 after conductive traces 650 have been defined thereon through selective etching of metallization layer 610 and seed layer 602. Each conductive trace 650 collectively comprises bonding pad 601 (optionally not discrete from metallization layer 610), seed layer 602, and metallization layer 610. Again, vias 104 may be blind vias instead of the depicted through-plane vias.

In some embodiments, forming a metallization layer upon the seed layer using a metal nanoparticle composition may comprise a hot pressing operation, in which at least a portion of the metal nanoparticles within a metal nanoparticle composition undergo consolidation under the hot pressing conditions. Illustrative hot pressing conditions may include a temperature of about 200° C. to about 270° C. and a pressure of about 500 psi to about 2500 psi. Hot pressing may take place over about 30 minutes to about 90 minutes, although longer or shorter times may also be suitable. Consolidation of metal nanoparticles within the vias may also take place at this time, if not already consolidated previously.

Metals within the metallization layer are not particularly limited and may be any metal that will suitably bond to the seed layer. In non-limiting examples, the metal within the metallization layer may include, but is not limited to, copper, palladium, gold, or silver.

The thickness of the metallization layer (and conductive traces obtained therefrom) may vary over a wide range. In non-limiting examples, the metallization layer may be up to about 500 microns in thickness, such as within a range of about 300 microns to about 500 microns, or about 100 microns to about 400 microns, or about 10 microns to about 100 microns.

The metallized substrates described herein may comprise at least a portion of a printed circuit board, an interposer, a package substrate, or a plurality of the metallized substrates may be stacked upon one another in a printed circuit board. When stacked upon one another, the architecture of the various metallized substrates need not necessarily be the same as each other.

Embodiments disclosed herein include those of the following clauses:

A. Metallized substrates. The metallized substrates comprise: a base substrate having one or more vias extending between a first face and second face thereof, the base substrate comprising a glass substrate or a silicon substrate; and a via fill material within the one or more vias, the via fill material comprising: 1) a porous matrix material having a void space of about 30% to about 60% and comprising a plurality of electrically conductive particles bonded together with a cured silicate-reactive matrix material; and 2) a conductive network at least partially filling the void space within the porous matrix material, the conductive network comprising a plurality of metal nanoparticles that have been consolidated together with one another.

A1. A printed circuit board comprising the metallized substrate of A or a plurality of the metallized substrates of A that are stacked upon one another.

A2. An interposer comprising the metallized substrate of A.

B. Processes for making a metallized substrate. The processes comprise: providing a base substrate having one or more vias defined therein and extending between a first face and a second face of the base substrate, the base substrate comprising a glass substrate or a silicon substrate; depositing a via fill precursor comprising a plurality of electrically conductive particles and a silicate-reactive matrix material within the one or more vias; curing the fill material precursor to form a porous matrix material having a void space of about 30% to about 60%; introducing a metal nanoparticle composition into at least a portion of the void space; and at least partially consolidating metal nanoparticles of the metal nanoparticle composition with one another in the void space to form a conductive network at least partially filling the void space.

Embodiments A, A1, A2, and B may have one or more of the following additional elements in any combination:

Element 1: wherein the cured silicate-reactive matrix material comprises a cured liquid glass binder.

Element 1A: wherein the silicate-reactive matrix material comprises a liquid glass binder.

Element 2: wherein the electrically conductive particles comprise one or more particles selected from the group consisting of micron-size metal particles, chopped metal filaments, metal nanowires, carbon nanotubes, graphene, a graphite material, and any combination thereof.

Element 3: wherein the electrically conductive particles have a diameter no larger than about 1/10^{th} a diameter of the one or more vias.

Element 4: wherein the electrically conductive particles are elongated and have a length no larger than about ¾^{th} of the diameter of the one or more vias.

Element 5: wherein a mass ratio of the electrically conductive particles to the cured silicate-reactive matrix material to in the via fill material ranges from about 6:1 to about 30:1.

Element 6: wherein the cured silicate-reactive matrix material is chemically bonded to a wall surface of the one or more vias.

Element 7: wherein the electrically conductive particles comprise at least micron-size copper particles.

Element 8: wherein the metal nanoparticles comprise copper nanoparticles.

Element 9: wherein the one or more vias have a diameter up to about 500 microns.

Element 10: wherein the metallized substrates further comprise one or more conductive traces defined upon at least one of the first face or the second face of the base substrate and in electrical communication with the via fill material

Element 11: wherein the one or more conductive traces are located upon a seed layer adhered to the first face or the second face of the base substrate, the seed layer being electrically conductive and comprising a cured silicate-reactive matrix material and a plurality of electrically conductive particles mixed with the cured silicate-reactive matrix material, and wherein the one or more conductive traces directly contact the via fill material or indirectly contact the via fill material by way of a bonding pad.

Element 11A: wherein the one or more conductive traces are located upon a seed layer adhered to the first face or the second face of the base substrate, the seed layer being electrically conductive and comprising a cured silicate-reactive matrix material and a plurality of electrically conductive particles mixed with the cured silicate-reactive matrix material.

Element 12: wherein the seed layer has a thickness ranging from about 1 micron to about 30 microns.

Element 13: wherein the electrically conductive particles in the seed layer comprise micron-size metal particles.

Element 14: wherein the metal nanoparticle composition is introduced into the one or more vias in at least a portion of the void space by pressure infiltration, vacuum infiltration, or any combination thereof.

Element 15: wherein the process further comprises depositing a seed layer upon at least a portion of the base substrate, the seed layer comprising a silicate-reactive matrix material and a plurality of electrically conductive particles; curing the silicate-reactive matrix material to form a cured silicate-reactive matrix material; optionally mechanically polishing the seed layer; and forming one or more conductive traces upon at least a portion of the seed layer, the one or more conductive traces being in electrical communication with the via fill material.

By way of non-limiting example, exemplary combinations applicable to A, A1, A2, and B include, but are not limited to, 1 and/or 1A, and 2; 1 and/or 1A, and 3 and/or 4; 1 and/or 1A, and 2 and 3; 1 and/or 1A, and 2 and 4; 1 and/or 1A, and 2-4; 1 and/or 1A, and 5; 1 and/or 1A, and 6; 1 and/or 1A, and 7; 1 and/or 1A, and 8; 1 and/or 1A, and 7 and 8; 1 and/or 1A, and 9; 1 and/or 1A, and 10; 1 and/or 1A, 10, and 11 or 11A; 1 and/or 1A, and 12; 1 and/or 1A, and 13; 1 and/or 1A, and 14; 2, and 3 or 4; 2-4; 2 and 5; 2 and 6; 2 and 7; 2 and 8; 2, 7, and 8; 2 and 9; 2 and 10; 2 and 11 or 11A; 2 and 12; 2 and 13; 2 and 14; 3 and/or 4, and 5; 3 and/or 4, and 6; 3 and/or 4, and 7; 3 and/or 4, and 8; 3 and/or 4, 7 and 8; 3 and/or 4, and 9; 3 and/or 4, and 10; 3 and/or 4, and 11 or 11A; 3 and/or 4, and 12; 3 and/or 4, and 13; 3 and/or 4, and 14; 5 and 6; 5 and 7; 5 and 8; 5, 7 and 8; 5 and 9; 5 and 10; 5, and 11 or 11A; 5 and 12; 5 and 13; 5 and 14; 6 and 7; 6 and 8; 6, 7 and 8; 6 and 9; 6 and 10; 6, and 11 or 11A; 6 and 12; 6 and 13; 6 and 14; 7 and 8; 7 and 9; 7 and 10; 7, and 11 or 11A; 7 and 12; 7 and 13; 7 and 14; 8 and 9; 8 and 10; 8, and 11 or 11A; 8 and 12; 8 and 13; 8 and 14; 9 and 10; 9, and 11 or 11A; 9 and 12; 9 and 13; 9 and 14; 10, and 11 or 11A; 10 and 12; 10 and 13; 10 and 14; 12 and 13; 12 and 14; and 13 and 14. Any of the foregoing may be in further combination with 15.

The present disclosure is further directed to the following non-limiting clauses:
Clause 1. A metallized substrate comprising:
   a base substrate having one or more vias terminating in the base substrate, extending between a first face and second face of the base substrate, or any combination thereof, the base substrate comprising a glass substrate or a silicon substrate; and
   a via fill material within the one or more vias, the via fill material comprising:
      1) a porous matrix material having a void space of about 30% to about 60% and comprising a plurality of electrically conductive particles; and
      2) a conductive network at least partially filling the void space within the porous matrix material, the conductive network comprising a plurality of metal nanoparticles that have been consolidated together with one another.
Clause 2. The metallized substrate of clause 1, wherein the electrically conductive particles are bonded together with a cured silicate-reactive matrix material.
Clause 3. The metallized substrate of clause 2, wherein the cured silicate-reactive matrix material comprises a cured liquid glass binder.
Clause 4. The metallized substrate of clause 2 or clause 3, wherein a mass ratio of the electrically conductive particles to the cured silicate-reactive matrix material in the via fill material ranges from about 6:1 to about 30:1.
Clause 5. The metallized substrate of any one of clauses 2-4, wherein the cured silicate-reactive matrix material is also chemically bonded to a wall surface of the one or more vias.
Clause 6. The metallized substrate of any one of clauses 1-5, wherein the electrically conductive particles comprise one or more particles selected from the group consisting of micron-size metal particles, chopped metal filaments, metal nanowires, carbon nanotubes, graphene, a graphite material, and any combination thereof.
Clause 7. The metallized substrate of any one of clauses 1-6, wherein the electrically conductive particles have a diameter no larger than about 1/10^{th} a diameter of the one or more vias, the electrically conductive particles are elongated and have a length no larger than about ¾^{th} of the diameter of the one or more vias, or any combination thereof.
Clause 8. The metallized substrate of any one of clauses 1-7, wherein the electrically conductive particles comprise at least micron-size copper particles.
Clause 9. The metallized substrate of clause 8, wherein the metal nanoparticles comprise copper nanoparticles.
Clause 10. The metallized substrate of any one of clauses 1-9, wherein the one or more vias have a diameter up to about 500 microns.
Clause 11. The metallized substrate of any one of clauses 1-10, further comprising:
   one or more conductive traces defined upon at least one of the first face or the second face of the base substrate and in electrical communication with the via fill material.
Clause 12. The metallized substrate of clause 11, wherein the one or more conductive traces are located upon a seed layer adhered to at least one of the first face or the second face of the base substrate, the seed layer being electrically conductive and comprising a cured silicate-reactive matrix material and a second plurality of electrically conductive particles mixed with the cured silicate-reactive matrix material, and wherein the one or more conductive traces directly contact the via fill material or indirectly contact the via fill material by way of a bonding pad.
Clause 13. The metallized substrate of clause 12, wherein the seed layer has a thickness ranging from about 1 micron to about 30 microns.
Clause 14. The metallized substrate of clause 12, wherein the second plurality of electrically conductive particles in the seed layer comprise micron-size metal particles, metal nanoparticles, or any combination thereof.
Clause 15. A printed circuit board comprising the metallized substrate of any one of clauses 1-14 or a plurality of the metallized substrates of any one of clauses 1-14 that are stacked upon one another.
Clause 16. The printed circuit board of clause 15, wherein the electrically conductive particles are bonded together with a cured silicate-reactive matrix material.
Clause 17. The printed circuit board of clause 16, wherein one or more conductive traces are defined upon at least one of the first face or the second face of the base substrate and in electrical communication with the via fill material.
Clause 18. The printed circuit board of clause 17, wherein the one or more conductive traces are located upon a seed layer adhered to at least one of the first face or the second face of the base substrate, the seed layer being electrically conductive and comprising a cured silicate-reactive matrix material and a second plurality of electrically conductive particles mixed with the cured silicate-reactive matrix material.
Clause 19. The printed circuit board of clause 15, wherein one or more conductive traces are defined upon at least one of the first face or the second face of the base substrate and in electrical communication with the via fill material.
Clause 20. The printed circuit board of clause 19, wherein the one or more conductive traces are located upon a seed layer adhered to at least one of the first face or the second face of the base substrate, the seed layer being electrically conductive and comprising a cured silicate-reactive matrix material and a second plurality of electrically conductive particles mixed with the cured silicate-reactive matrix material.
Clause 21. An interposer comprising the metallized substrate of any one of clauses 1 or 6-14.
Clause 22. An interposer comprising the metallized substrate of any one of clauses 2-14.
Clause 23. A process comprising:
   providing a base substrate having one or more vias defined therein, the one or more vias terminating in the base substrate, extending between a first face and a second face of the base substrate, or any combination thereof, and the base substrate comprising a glass substrate or a silicon substrate;
   depositing a via fill precursor comprising a plurality of electrically conductive particles within the one or more vias;
   curing the via fill precursor to form a porous matrix material having a void space of about 30% to about 60%;
   introducing a metal nanoparticle composition into at least a portion of the void space; and
   at least partially consolidating metal nanoparticles of the metal nanoparticle composition with one another in the void space to form a conductive network at least partially filling the void space.
Clause 24. The method of clause 23, wherein the via fill precursor further comprises a silicate-reactive matrix material, the silicate-reactive matrix material forming a cured silicate-reactive matrix material after curing and bonding the electrically conductive particles together.
Clause 25. The process of clause 24, wherein the silicate-reactive matrix material comprises a liquid glass binder.
Clause 26. The process of any one of clauses 23-25, wherein the electrically conductive particles comprise one or more particles selected from the group consisting of micron-size metal particles, chopped metal filaments, metal nanowires, carbon nanotubes, graphene, and any combination thereof.
Clause 27. The process of any one of clauses 23-26, wherein the metal nanoparticle composition is introduced into the one or more vias in at least a portion of the void space by pressure infiltration, vacuum infiltration, or any combination thereof.
Clause 28. The process of any one of clauses 23-27, wherein the electrically conductive particles have a diameter no larger than about 1/10^{th} a diameter of the one or more vias, the electrically conductive particles are elongated and have a length no larger than about ¾^{th} of the diameter of the one or more vias, or any combination thereof.
Clause 29. The process of any one of clauses 23-28, wherein the electrically conductive particles comprise at least micron-size copper particles.
Clause 30. The process of clause 29, wherein the metal nanoparticles comprise copper nanoparticles.
Clause 31. The process of any one of clauses 23-30, wherein the one or more vias have a diameter up to about 500 microns.
Clause 32. The process of any one of clauses 23-31, further comprising:
   depositing a seed layer upon at least a portion of the base substrate, the seed layer comprising a silicate-reactive matrix material and a second plurality of electrically conductive particles;
   curing the silicate-reactive matrix material to form a cured silicate-reactive matrix material;
   optionally, mechanically polishing the seed layer; and
   forming one or more conductive traces upon at least a portion of the seed layer, the one or more conductive traces being in electrical communication with the via fill material.
Clause 33. The process of any one of clauses 23-32, wherein the via fill precursor and the metal nanoparticle composition are combined together prior to being deposited and introduced into the one or more vias.
Clause 34. The process of any one of clauses 23-32, wherein the via fill precursor and the metal nanoparticle composition are deposited and introduced separately into the one or more vias.

One or more illustrative embodiments incorporating the features of the present disclosure are presented herein. Not all features of a physical implementation are described or shown in this application for the sake of clarity. It is understood that in the development of a physical embodiment incorporating the present disclosure, numerous implementation-specific decisions must be made to achieve the developer's goals, such as compliance with system-related, business-related, government-related and other constraints, which vary by implementation and from time to time. While a developer's efforts might be time-consuming, such efforts would be, nevertheless, a routine undertaking for those of ordinary skill in the art and having benefit of this disclosure.

Therefore, the present disclosure is well adapted to attain the ends and advantages mentioned as well as those that are inherent therein. The particular embodiments disclosed above are illustrative only, as the present disclosure may be modified and practiced in different but equivalent manners apparent to those skilled in the art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present invention. The disclosure herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some amount. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the element that it introduces.

1. A metallized substrate comprising:
a base substrate having one or more vias terminating in the base substrate, extending between a first face and second face of the base substrate, or any combination thereof, the base substrate comprising a glass substrate or a silicon substrate; and
a via fill material within the one or more vias, the via fill material comprising:
1) a porous matrix material having a void space of about 30% to about 60% and comprising a plurality of electrically conductive particles; and
2) a conductive network at least partially filling the void space within the porous matrix material, the conductive network comprising a plurality of metal nanoparticles that have been consolidated together with one another.

2. The metallized substrate of claim 1, wherein the electrically conductive particles are bonded together with a cured silicate-reactive matrix material, wherein the silicate-reactive matrix material cures at a temperature within a range of room temperature to about 100° C.

3. The metallized substrate of claim 2, wherein the cured silicate-reactive matrix material comprises a cured liquid glass binder.

4. The metallized substrate of claim 2, wherein a mass ratio of the electrically conductive particles to the cured silicate-reactive matrix material in the via fill material ranges from about 6:1 to about 30:1.

5. The metallized substrate of claim 2, wherein the cured silicate-reactive matrix material is also chemically bonded to a wall surface of the one or more vias.

6. The metallized substrate of claim 1, wherein the electrically conductive particles comprise one or more particles selected from the group consisting of micron-size metal particles, chopped metal filaments, metal nanowires, carbon nanotubes, graphene, a graphite material, and any combination thereof.

7. The metallized substrate of claim 1, wherein the electrically conductive particles have a diameter no larger than about 1/10^{th} a diameter of the one or more vias, the electrically conductive particles are elongated and have a length no larger than about ¾^{th} of the diameter of the one or more vias, or any combination thereof.

8. The metallized substrate of claim 1, wherein the electrically conductive particles comprise at least micron-size copper particles.

9. The metallized substrate of claim 8, wherein the metal nanoparticles comprise copper nanoparticles.

10. The metallized substrate of claim 1, wherein the one or more vias have a diameter up to about 500 microns.

11. The metallized substrate of claim 1, further comprising: one or more conductive traces defined upon at least one of the first face or the second face of the base substrate and in electrical communication with the via fill material.

12. The metallized substrate of claim 11, wherein the one or more conductive traces are located upon a seed layer adhered to at least one of the first face or the second face of the base substrate, the seed layer being electrically conductive and comprising a cured silicate-reactive matrix material and a second plurality of electrically conductive particles mixed with the cured silicate-reactive matrix material, and wherein the one or more conductive traces directly contact the via fill material or indirectly contact the via fill material by way of a bonding pad.

13. The metallized substrate of claim 12, wherein the seed layer has a thickness ranging from about 1 micron to about 30 microns.

14. The metallized substrate of claim 12, wherein the second plurality of electrically conductive particles in the seed layer comprises micron-size metal particles, metal nanoparticles, or any combination thereof.

15. A printed circuit board comprising the metallized substrate of claim 1 or a plurality of the metallized substrates of claim 1 that are stacked upon one another.

16. The printed circuit board of claim 15, wherein the electrically conductive particles are bonded together with a cured silicate-reactive matrix material, wherein the silicate-reactive matrix material cures at a temperature within a range of about room temperature to about 100° C.

17. The printed circuit board of claim 16, wherein one or more conductive traces are defined upon at least one of the first face or the second face of the base substrate and in electrical communication with the via fill material.

18. The printed circuit board of claim 17, wherein the one or more conductive traces are located upon a seed layer adhered to at least one of the first face or the second face of the base substrate, the seed layer being electrically conductive and comprising a cured silicate-reactive matrix material and a second plurality of electrically conductive particles mixed with the cured silicate-reactive matrix material.

19. The printed circuit board of claim 15, wherein one or more conductive traces are defined upon at least one of the first face or the second face of the base substrate and in electrical communication with the via fill material.

20. The printed circuit board of claim 19, wherein the one or more conductive traces are located upon a seed layer adhered to at least one of the first face or the second face of the base substrate, the seed layer being electrically conductive and comprising a cured silicate-reactive matrix material and a second plurality of electrically conductive particles mixed with the cured silicate-reactive matrix material.

21. An interposer comprising the metallized substrate of claim 1.

22. An interposer comprising the metallized substrate of claim 2.

23. A process comprising:
providing a base substrate having one or more vias defined therein, the one or more vias terminating in the base substrate, extending between a first face and a second face of the base substrate, or any combination thereof, and the base substrate comprising a glass substrate or a silicon substrate;
depositing a via fill precursor comprising a plurality of electrically conductive particles within the one or more vias;
curing the via fill precursor to form a porous matrix material having a void space of about 30% to about 60%;
introducing a metal nanoparticle composition into at least a portion of the void space; and
at least partially consolidating metal nanoparticles of the metal nanoparticle composition with one another in the void space to form a conductive network at least partially filling the void space.

24. The method of claim 23, wherein the via fill precursor further comprises a silicate-reactive matrix material, the silicate-reactive matrix material forming a cured silicate-reactive matrix material after curing at a temperature within a range of about room temperature to about 100° C. and bonding the electrically conductive particles together.

25. The process of claim 24, wherein the silicate-reactive matrix material comprises a liquid glass binder.

26. The process of claim 23, wherein the electrically conductive particles comprise one or more particles selected from the group consisting of micron-size metal particles, chopped metal filaments, metal nanowires, carbon nanotubes, graphene, and any combination thereof.

27. The process of claim 23, wherein the metal nanoparticle composition is introduced into the one or more vias in at least a portion of the void space by pressure infiltration, vacuum infiltration, or any combination thereof.

28. The process of claim 23, wherein the electrically conductive particles have a diameter no larger than about 1/10^{th} a diameter of the one or more vias, the electrically conductive particles are elongated and have a length no larger than about ¾^{th} of the diameter of the one or more vias, or any combination thereof.

29. The process of claim 23, wherein the electrically conductive particles comprise at least micron-size copper particles.

30. The process of claim 29, wherein the metal nanoparticles comprise copper nanoparticles.

31. The process of claim 23, wherein the one or more vias have a diameter up to about 500 microns.

32. The process of claim 23, further comprising:
depositing a seed layer upon at least a portion of the base substrate, the seed layer comprising a silicate-reactive matrix material and a second plurality of electrically conductive particles;
curing the silicate-reactive matrix material to form a cured silicate-reactive matrix material;
optionally, mechanically polishing the seed layer; and
forming one or more conductive traces upon at least a portion of the seed layer, the one or more conductive traces being in electrical communication with the via fill material.

33. The process of claim 23, wherein the via fill precursor and the metal nanoparticle composition are combined together prior to being deposited and introduced into the one or more vias.

34. The process of claim 23, wherein the via fill precursor and the metal nanoparticle composition are deposited and introduced separately into the one or more vias.
